(19) United States
(12) Patent Application Publication
(10) Pub. No.: US 2026/0090328 A1
(43) Pub. Date: Mar. 26, 2026

(54) SUBSTRATE PROCESSING APPARATUS

(71) Applicant: SCREEN Holdings Co., Ltd., Kyoto (JP)

(72) Inventor: Ichiro MITSUYOSHI, Kyoto (JP)

(21) Appl. No.: 19/112,583

(22) PCT Filed: May 24, 2023
(86) PCT No.: PCT/JP2023/019338

§ 371 Date: Mar. 17, 2025

(30) Foreign Application Priority Data
Sep. 22, 2022 (JP) 2022-151705

(51) Int. Cl. H10P 72/30; B08B 3/04; H10P 72/00

(52) U.S. Cl. CPC H10P 72/3211; B08B 3/04; H10P 72/0414; H10P 72/0426

(57) ABSTRACT

In a substrate processing apparatus, an orientation converting area is provided between a transfer block and a batch processing area; a single-wafer transporting area is positioned adjacently to the transfer block and the orientation converting area; and the single-wafer processing area is positioned adjacently to the single-wafer transporting area. A center robot in the single-wafer transporting area transports the substrate from the second orientation converting mechanism in the orientation converting area, to the single-wafer processing chambers in the single-wafer processing area, and to the buffering unit. The center robot includes a horizontally movable hand that holds a substrate in a horizontal orientation, and a lifting stage that raises and lowers the hand, and the lifting stage has a fixed position in the horizontal direction.

### TECHNICAL FIELD

The present invention relates to a substrate processing apparatus for processing a substrate. Examples of the substrate include a semiconductor substrate, a substrate for a flat panel display (FPD), a glass substrate for a photomask, a substrate for an optical disk, a substrate for a magnetic disk, a ceramic substrate, and a substrate for a solar cell. Examples of the FPD include a liquid crystal display device and an organic electroluminescence (EL) display device.

### BACKGROUND ART

As a conventional substrate processing apparatus, there is a hybrid substrate processing apparatus including a batch processing module (batch processing unit) that processes a plurality of substrates as a batch, and a single-wafer processing module (single-wafer processing unit) that processes each one of the substrates having been processed by the batch processing module one by one (see, for example, Patent Literatures 1 and 2).

The substrate processing apparatus according to Patent Literature 1 includes: a loading port used for receiving a cassette; a first robot; two rotating mechanisms for rotating a wafer to and from a vertical orientation from and to a horizontal orientation; two baths arranged in a row between the two rotating mechanisms; a second robot capable of transporting a vertically-orientated wafer between the two rotating mechanisms and the two baths; a plurality of single-wafer cleaning modules performing cleaning and drying; and a third robot.

The plurality of single-wafer cleaning modules are arranged in a row. The first robot takes out five wafers at a time from a cassette, and transports the five wafers to the first rotating mechanism. The third robot takes out a wafer from the second rotating mechanism, and transports the wafer to the single-wafer cleaning module. The first robot takes out one wafer from one of the plurality of single-wafer cleaning modules, and returns the wafer into the cassette.

The substrate processing apparatus according to Patent Literature 2 includes a loading/unloading unit having a cassette placing table; a single-wafer processing unit (area); an interface unit; and a batch processing unit (area). The substrate processing apparatus according to Patent Literature 3 includes an orientation converting mechanism.

### CITATION LIST

### Patent Literature

Patent Literature 1: JP 2016-502275 A

Patent Literature 2: JP 2021-064652 A

Patent Literature 3: JP 2018-056341 A

### SUMMARY OF INVENTION

### Technical Problem

Such conventional substrate processing apparatuses have the following problems. For example, in the substrate processing apparatus according to Patent Literature 1, the first robot takes out five wafers as a batch from a cassette while moving along the plurality of single-wafer cleaning modules, and transports the five wafers to the first rotating mechanism. The first robot also takes out one wafer from one of the plurality of single-wafer cleaning modules while moving along the plurality of single-wafer cleaning modules, and returns the wafer to the cassette. Therefore, there is a possibility that the first robot is busy, and that the throughput of the substrate processing apparatus is deteriorated.

In addition, in the substrate processing apparatus according to Patent Literature 2, the loading/unloading unit, the single-wafer processing unit, the interface unit, and the batch processing unit are arranged in the order listed herein. The substrate taken out from the cassette is sent from the loading/unloading unit to the interface unit by passing through the single-wafer processing unit. In the interface unit, a plurality of vertically oriented substrates are put into a lot for the process of the batch processing unit. In other words, a lot is not directly transported from the loading/unloading unit to the batch processing unit. Therefore, the throughput of the substrate processing apparatus may deteriorate.

The present invention has been made in view of such circumstances, and an object of the present invention is to provide a substrate processing apparatus for improving the throughput.

### Solution to Problem

In order to achieve such an object, the present invention uses the following configurations. That is, a substrate processing apparatus according to the present invention is a substrate processing apparatus configured to perform a batch process in which a plurality of substrates are processed as a batch, and a single-wafer process in which one substrate is processed at a time, continuously, the substrate processing apparatus including: a carrier placing shelf on which a carrier is placed, with the carrier storing a plurality of substrates that are in a horizontal orientation at a predetermined interval along a vertical direction; a transfer block that is positioned adjacently to the carrier placing shelf, a processing block positioned adjacently to the transfer block; and a substrate placing unit where a substrate is placed, in which the transfer block includes: a first orientation converting mechanism that converts the plurality of substrates in the horizontal orientation, the plurality of substrates having been taken out from the carrier, to a vertical orientation; and a substrate handling mechanism that transports the plurality of substrates in the horizontal orientation as a batch, to and from the carrier placed on the carrier placing shelf, the first orientation converting mechanism, and the substrate placing unit, the processing block includes: a batch processing area extending in a direction separating from the transfer block; a batch substrate transporting area provided along the batch processing area, and having one end extending to the transfer block and another end extending in a direction separating from the transfer block; an orientation converting area provided between the transfer block and the batch processing area; a single-wafer transporting area positioned adjacently to the transfer block and to the orientation converting area; and a single-wafer processing area positioned adjacently to the single-wafer transporting area, the batch processing area includes a plurality of batch processing baths that process the plurality of substrates in the vertical orientation as a batch, and that are arranged in a direction in which the batch processing area extends, the orientation converting area is provided with a second orientation converting mechanism that converts the plurality of substrates having been subjected to the batch process, from the vertical orientation to the horizontal orientation, the batch substrate transporting area is provided with a batch substrate transporting mechanism that transfers the plurality of substrates in the vertical orientation to and from a substrate delivery position that is defined in the transfer block, the plurality of batch processing baths, and the second orientation converting mechanism, the single-wafer processing area has a plurality of single-wafer processing chambers each of which processes one substrate in the horizontal orientation at a time, the single-wafer transporting area has a horizontal substrate transporting mechanism that is capable of transporting one substrate in the horizontal orientation at a time, from the second orientation converting mechanism, to the plurality of single-wafer processing chambers, and to the substrate placing unit, and the horizontal substrate transporting mechanism includes a hand that is horizontally movable and that holds a substrate in the horizontal orientation, and a lifting stage that raises and lowers the hand and that is at a fixed position in a horizontal direction.

With the substrate processing apparatus according to the present invention, the orientation converting area (including the second orientation converting mechanism) is provided between the transfer block and the batch processing area. The single-wafer transporting area is positioned adjacently to the transfer block and the orientation converting area. The single-wafer processing area (including the plurality of single-wafer processing chambers) is positioned adjacently to the single-wafer transporting area. A horizontal position of the lifting stage included in the horizontal substrate transporting mechanism, which is provided in the single-wafer transporting area, is fixed. Therefore, the transfer block, the second orientation converting mechanism, and the plurality of single-wafer processing chambers can be positioned around the horizontal substrate transporting mechanism. With this, for example, because the distance by which the substrate is transported by the horizontal substrate transporting mechanism can be kept short, the substrate can be transported efficiently. Furthermore, the batch substrate transporting mechanism can transport a plurality of substrates between the substrate delivery position in the transfer block, the plurality of batch processing baths, and the second orientation converting mechanism. As a result, the throughput can be improved.

Furthermore, preferably, in the substrate processing apparatus described above, the second orientation converting mechanism includes a substrate standby area and an orientation conversion executing area that are arranged in the direction in which the batch processing area extends, the substrate standby area has a substrate holding unit that holds the plurality of substrates transported by the batch substrate transporting mechanism, in the vertical orientation, the orientation conversion executing area has an orientation converting unit including: two chucks that hold the plurality of substrates; a vertically rotating unit that rotates the two chucks about a horizontal axis; and a horizontally moving unit that moves the two chucks and the vertically rotating unit from a position above the substrate holding unit to a preset position in the orientation conversion executing area, and the orientation converting unit receives the plurality of substrates from the substrate holding unit by using the two chucks in the substrate standby area, and converts an orientation of the plurality of substrates from the vertical orientation to the horizontal orientation by using the vertically rotating unit in the orientation converting area.

In a width direction orthogonal to the direction in which the batch processing area extends, the orientation converting area in which the second orientation converting mechanism is disposed becomes smaller in width. Therefore, the width of the substrate processing apparatus can be kept small.

Furthermore, in the substrate processing apparatus described above, the horizontal substrate transporting mechanism is preferably suspended at a position above the single-wafer transporting area. It is therefore possible to prevent the horizontal substrate transporting mechanism from becoming contaminated by the droplets dripping from the wet substrate. For example, it is possible to prevent a failure of the horizontal substrate transporting mechanism due to such a contamination.

Furthermore, in the substrate processing apparatus described above, preferably, the single-wafer processing area is provided on an opposite side of the transfer block with respect to the single-wafer transporting area, and is provided adjacently to the orientation converting area. The transfer block has a relatively large width in the width direction orthogonal to the direction in which the batch processing area extends. Because the single-wafer transporting area is disposed in a manner facing the transfer block, the width of the substrate processing apparatus can be kept small.

Furthermore, in the substrate processing apparatus described above, the processing block preferably further includes a second single-wafer processing area provided on an opposite side of the orientation converting area with respect to the single-wafer transporting area. Because the single-wafer processing area becomes larger, a larger number of single-wafer processing chambers can be arranged. Therefore, it is possible to improve the throughput of the substrate processing device.

Furthermore, a substrate processing apparatus according to the present invention is a substrate processing apparatus configured to perform a batch process in which a plurality of substrates are processed as a batch, and a single-wafer process in which one substrate is processed at a time, continuously, the substrate processing apparatus including: a carrier placing shelf on which a carrier is placed, with the carrier storing a plurality of substrates that are in a horizontal orientation at a predetermined interval along a vertical direction; a transfer block that is positioned adjacently to the carrier placing shelf; a processing block that is positioned adjacently to the transfer block; the transfer block includes: a first orientation converting mechanism that converts the plurality of substrates in the horizontal orientation, the plurality of substrates having been taken out from the carrier, to a vertical orientation; a horizontal substrate transporting mechanism that transports a substrate in the horizontal orientation, the processing block includes: a batch processing area extending in a direction separating from the transfer block; a batch substrate transporting area provided along the batch processing area, and having one end extending to the transfer block and another end extending in a direction separating from the transfer block; an orientation converting area provided between the transfer block and the batch processing area; a single-wafer transporting area positioned adjacently to the transfer block and to the orientation converting area; and a single-wafer processing area positioned adjacently to the single-wafer transporting area, the batch processing area is provided with a plurality of batch processing baths that process the plurality of substrates in the vertical orientation as a batch, and that are arranged in a direction in which the batch processing area extends, the orientation converting area is provided with a second orientation converting mechanism that converts the plurality of substrates having been subjected to the batch process, from the vertical orientation to the horizontal orientation, the batch substrate transporting area is provided with a batch substrate transporting mechanism that transfers the plurality of substrates in the vertical orientation to and from a substrate delivery position that is defined in the transfer block, the plurality of batch processing baths, and the second orientation converting mechanism, the single-wafer processing area has a plurality of single-wafer processing chambers each of which processes one substrate in the horizontal orientation at a time, the horizontal substrate transporting mechanism is capable of transporting a substrate in the horizontal orientation from and to the carrier placed on the carrier placing shelf, the first orientation converting mechanism, the second orientation converting mechanism, and the plurality of single-wafer processing chambers, and the horizontal substrate transporting mechanism includes a hand that is horizontally movable and that holds a substrate in the horizontal orientation, and a lifting stage that raises and lowers the hand and that is at a fixed position in a horizontal direction.

With the substrate processing apparatus according to the present invention, the orientation converting area (including the second orientation converting mechanism) is provided between the transfer block and the batch processing area. The single-wafer transporting area is positioned adjacently to the transfer block and the orientation converting area. The single-wafer processing area (including the plurality of single-wafer processing chambers) is positioned adjacently to the single-wafer transporting area. Furthermore, a horizontal position of the lifting stage included in the horizontal substrate transporting mechanism provided in the transfer block is fixed. Therefore, the carrier placed on the carrier placing shelf, the first orientation converting mechanism, the second orientation converting mechanism, and the plurality of single-wafer processing chambers can be positioned around the horizontal substrate transporting mechanism. With this, for example, because the distance by which the substrate is transported by the horizontal substrate transporting mechanism can be kept short, the substrate can be transported efficiently.

Furthermore, the batch substrate transporting mechanism can transport a plurality of substrates between the substrate delivery position in the transfer block, the plurality of batch processing baths, and the second orientation converting mechanism. In particular, the substrate taken out from the single-wafer processing chamber can be transported directly to the carrier on the carrier placing shelf. As a result, the throughput can be improved. Advantageous Effect of Invention With the substrate processing apparatus according to the present invention, it is possible to improve the throughput.

### BRIEF DESCRIPTION OF DRAWINGS

FIG. 1 is a plan view illustrating a schematic configuration of a substrate processing apparatus according to a first embodiment.

FIG. 2 is a side view illustrating a substrate handling mechanism.

FIG. 3(a) to 3(f) are side views for explaining a first orientation converting mechanism (an orientation changing unit and a pusher mechanism) included in a transfer block.

FIG. 4(a) is a plan view illustrating a second orientation converting mechanism, and FIG. 4(b) is a front view illustrating the second orientation converting mechanism.

FIG. 5 is a front view for explaining two chucks (a horizontal holder and a vertical holder) included in an orientation converting unit.

FIG. 6 is a flowchart for explaining an operation of the substrate processing apparatus.

FIG. 7 is a flowchart for explaining an operation of the second orientation converting mechanism.

FIG. 8(a) to 8(c) are front views for explaining a first half of the operation of the second orientation converting mechanism.

FIG. 9(a) to 9(c) are plan views for explaining a first half of an operation of the second orientation converting mechanism.

FIG. 10(a) to 10(c) are front views for explaining the latter half of the operation of the second orientation converting mechanism.

FIG. 11(a) to 11(c) are plan views for explaining the latter half of the operation of the second orientation converting mechanism.

FIG. 12(a) is a plan view illustrating a second orientation converting mechanism according to a second embodiment, and FIG. 12(b) is a front view illustrating the second orientation converting mechanism according to the second embodiment.

FIG. 13 is a plan view illustrating a schematic configuration of a substrate processing apparatus according to a third embodiment.

FIG. 14 is a plan view illustrating a schematic configuration of a substrate processing apparatus according to a modification.

FIG. 15 is a plan view illustrating a schematic configuration of a substrate processing apparatus according to a modification.

FIG. 16 is a side view illustrating a center robot according to a modification.

### FIRST EMBODIMENT

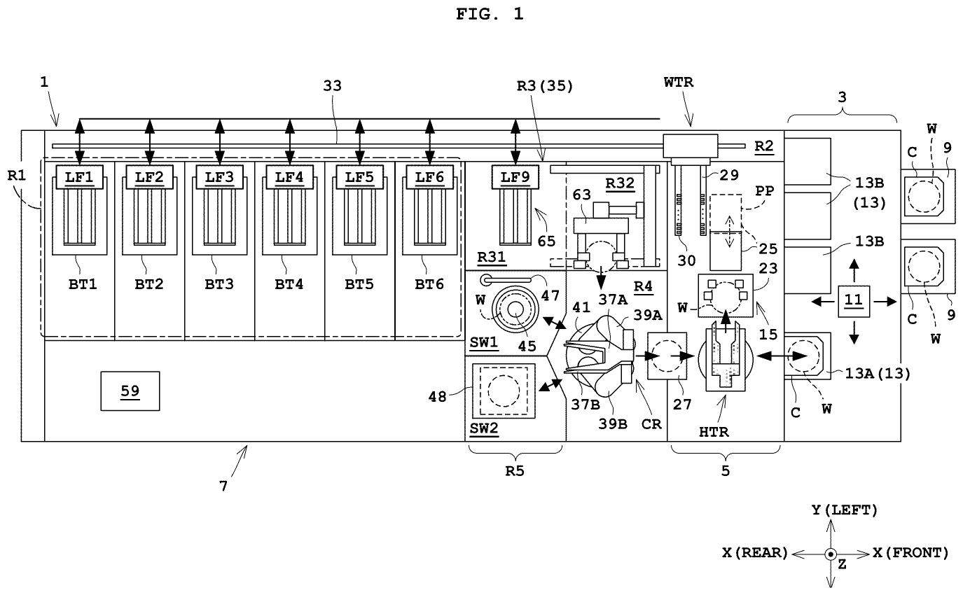

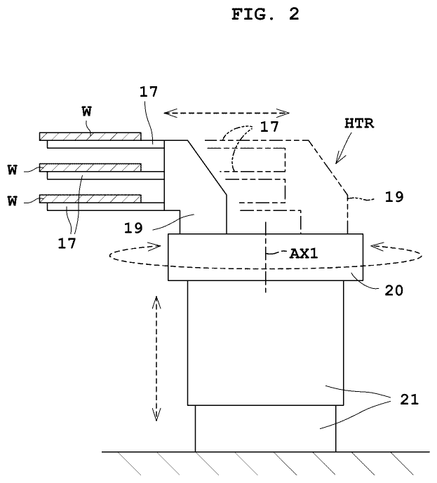

A first embodiment of the present invention will now be described with reference to drawings. FIG. 1 is a plan view illustrating a schematic configuration of a substrate processing apparatus 1 according to the first embodiment. FIG. 2 is a side view illustrating a substrate handling mechanism HTR.

### 1. Overall Configuration

FIG. 1 will now be referred to. The substrate processing apparatus 1 includes a stocker block 3, a transfer block 5, and a processing block 7. The stocker block 3, the transfer block 5, and the processing block 7 are arranged in a row along the horizontal direction in the order listed herein.

The substrate processing apparatus 1 performs processes such as a chemical liquid process, a cleaning process, and a drying process on the substrates W. The substrate processing apparatus 1 performs a batch process and a single-wafer process to the substrate W, continuously. That is, the substrate processing apparatus 1 performs a batch process and then performs a single-wafer process on the substrate W. The batch process is a processing method for processing a plurality of substrates W as a batch. The single-wafer process is a processing method for processing one substrates W at a time.

In the present specification, for convenience, a direction in which the stocker block 3, the transfer block 5, and the processing block 7 are arranged will be referred to as a “front-back direction X”. The front-back direction X is horizontal. Of the front-back direction X, the direction from the transfer block 5 toward the stocker block 3 will be referred to as “frontwards”. The direction opposite to the frontward direction will be referred to as “rearwards”. The horizontal direction orthogonal to the front-back direction X will be referred to as “width directions Y”. One of the width directions Y will be referred to as “rightwards”, as appropriate.

The direction opposite to the rightward direction will be referred to as “leftwards”. The direction perpendicular to the horizontal directions will be referred to as “vertical directions Z”. In FIG. 1, for example, front, rear, right, left, top, and bottom are indicated as appropriate, for reference.

### 2. Stocker Block

In the stocker block 3, at least one carrier C is housed. One, or two or more (e.g., two) loading ports 9 are provided to the stocker block 3. The stocker block 3 includes a carrier transporting mechanism (robot) 11 and shelves 13.

A carrier transporting mechanism 11 transports the carrier C between the loading port 9 and the shelves 13. The carrier transporting mechanism 11 includes a gripper that grips a protrusion provided to the top surface of the carrier C, or a hand that is kept in contact with the bottom surface of the carrier C to support the carrier C. The shelves 13 are classified into a shelf 13A for taking in and out the substrate W, and a shelf 13B for storage.

The shelf 13A is positioned adjacently to the transfer block 5. The shelf 13A may have a mechanism for attaching and detaching a lid to and from the carrier C. The shelves 13 include at least one shelf 13A. On the shelf 13A, a carrier C is placed. The carrier C stores therein a plurality of (e.g., twenty-five) substrates W in the horizontal orientation, at a predetermined interval therebetween (e.g., an interval of 10 mm) in the vertical direction Z. The substrates W are aligned in the thickness direction of the substrates W. As one example of the carrier C, a front opening unify pod (FOUP) is used. The FOUP is a sealed container. The carrier C may also be any type of container including an open container. The shelf 13A corresponds to a carrier placing shelf according to the present invention.

### 3. Transfer Block

The transfer block 5 is positioned adjacently to and on the rear side X of the stocker block 3. The transfer block 5 includes a substrate handling mechanism (robot) HTR, and a first orientation converting mechanism 15. The substrate handling mechanism HTR corresponds to the substrate handling mechanism according to the present invention.

The substrate handling mechanism HTR is positioned on the right side Y in the transfer block 5. The substrate handling mechanism HTR can transport a plurality of (e.g., twenty-five) substrates W in the horizontal orientation, between the carrier C placed on the shelf 13A, the first orientation converting mechanism 15, and the buffering unit 27 (to be described later).

FIG. 2 will now be referred to. The substrate handling mechanism HTR has a plurality of (e.g., twenty-five) hands 17. In FIG. 2, for the convenience of illustration, the substrate handling mechanism HTR includes three hands 17. Each of the hands 17 holds one substrate W.

The substrate handling mechanism HTR further includes a hand support 19, an advancing/retracting unit 20, and a rotating lift 21. The hand support 19 supports the plurality of hands 17. With this, the plurality of hands 17 move integrally. The advancing/retracting unit 20 advances and retracts the plurality of hands 17 by moving the hand support 19. The rotating lift 21 rotates the plurality of hands 17 and the like about a vertical axis AX1 by rotating the advancing/retracting unit 20 about the vertical axis AX1. Furthermore, the rotating lift 21 raises and lowers the plurality of hands 17 and the like by raising and lowering the advancing/retracting unit 20. The rotating lift 21 is fixed to a floor surface. That is, the rotating lift 21 does not move in the horizontal direction. Each of the advancing/retracting unit 20 and the rotating lift 21 includes an electric motor. The substrate handling mechanism HTR may also have a hand (not illustrated) for transporting one substrate W, separately from the hands 17 and the hand support 19.

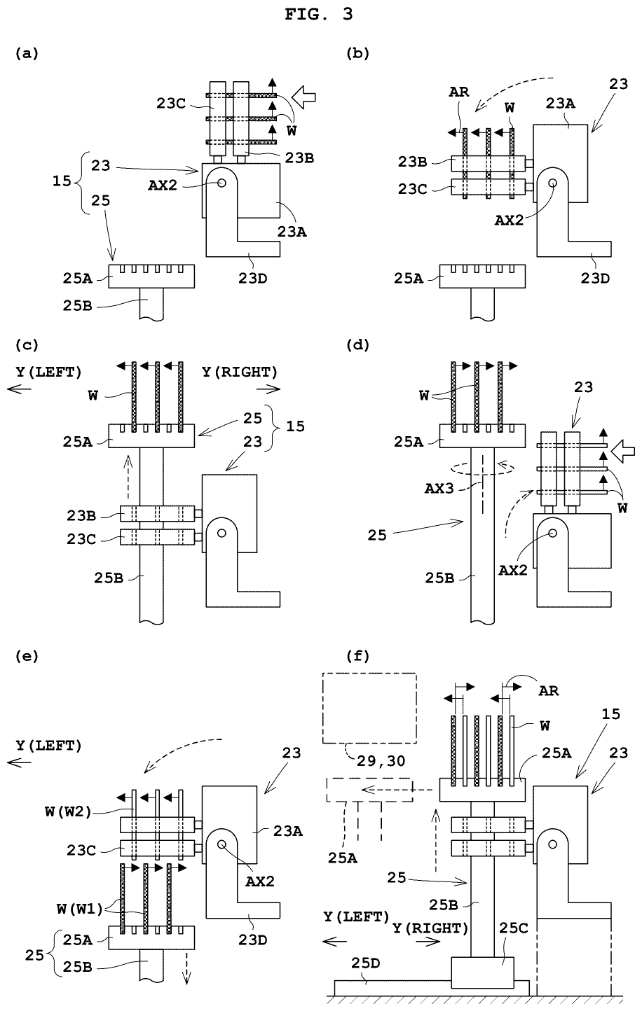

FIG. 1 will now be referred to. The first orientation converting mechanism 15 converts the orientation of the plurality of substrates W extracted from the carrier C, from the horizontal orientation to the vertical orientation. The first orientation converting mechanism 15 includes an orientation converting unit 23 and a pusher mechanism 25. In FIG. 1, the substrate handling mechanism HTR, the orientation converting unit 23, and the pusher mechanism 25 are arranged toward the left side Y, in the order listed herein. FIG. 3(a) to 3(f) are side views for explaining the first orientation converting mechanism 15 (the orientation converting unit 23 and the pusher mechanism 25) included in the transfer block 5.

As illustrated in FIGS. 1 and 3(a), the orientation converting unit 23 includes a support base 23A, a pair of horizontal holders 23B, a pair of vertical holders 23C, and a rotation driving unit 23D. The pair of horizontal holders 23B and the pair of vertical holders 23C are provided on the support base 23A. The horizontal holders 23B and the vertical holders 23C receive the plurality of substrates W transported by the substrate handling mechanism HTR. While the substrates W are in the horizontal orientation, the pair of horizontal holders 23B supports the substrates W from the bottom, in a manner in contact with the bottom surfaces of the respective substrates W. While the substrates W are in the vertical orientation, the pair of vertical holders 23C hold the substrates W.

The rotation driving unit 23D rotatably supports the support base 23A about a horizontal axis AX2. The rotation driving unit 23D also converts the orientation of the plurality of substrates W held by the holders 23B, 23C from a horizontal orientation to the vertical orientation, by rotating the support base 23A about the horizontal axis AX2.

As illustrated in FIGS. 1 and 3(f), the pusher mechanism 25 includes a pusher 25A, a rotating lift 25B, a horizontally moving unit 25° C., and a rail 25D. The pusher 25A supports the lower part of each of a plurality of (e.g., fifty) vertically oriented substrates W. In FIG. 3(a) to 3(f), the pusher 25A is enabled to support six substrates W, for the convenience of illustration.

The rotating lift 25B is connected to the bottom surface of the pusher 25A. The rotating lift 25B extends and contracts so as to raise and to lower the pusher 25A in up-and-down directions. The rotating lift 25B also rotates the pusher 25A about the vertical axis AX3. The horizontally moving unit 25° C. supports the rotating lift 25B. The horizontally moving unit 25C moves the pusher 25A and the rotating lift 25B horizontally, along the rail 25D. The rail 25D is provided in a manner extending in the width direction Y. Each of the rotation driving unit 23D, the rotating lift 25B, and the horizontally moving unit 25C has an electric motor.

An operation of the first orientation converting mechanism 15 will now be described. Batch processing baths BT1 to BT6, to be described later, in the processing block 7 processes, for example, fifty substrates W corresponding to two carriers C as a batch. The first orientation converting mechanism 15 converts the orientation of fifty substrates W in units of twenty-five. The first orientation converting mechanism 15 also arranges the plurality of substrates W face-to-face at a predetermined interval (half pitch). The half pitch is, for example, an interval of 5 mm. The pusher mechanism 25 transports the fifty substrates W to the transporting mechanism WTR.

The twenty-five substrates W in the first carrier C will be described as substrates W1 of a first substrate group. The twenty-five substrates W in the second carrier C will be described as substrates W2 of a second substrate group. Furthermore, in FIG. 3(a) to 3(f), for the convenience of illustration, a description will be made assuming that the number of substrates W1 in the first substrate group is three and the number of substrates W2 in the second substrate group is three. When the substrates W1 and the substrates W2 are not particularly distinguished from each other, the substrates W1 and W2 will be referred to as “substrates W”.

FIG. 3(a) will now be referred to. The orientation converting unit 23 causes the holders 23B, 23C to receives the twenty-five substrates W1 of the first substrate group, having been transported by the substrate handling mechanism HTR. At this time, the twenty-five substrates W1 are in the horizontal orientation, with their device surfaces facing upwards. The twenty-five substrates W1 are arranged at a predetermined interval (full pitch). The full pitch is, for example, an interval of 10 mm. The full pitch will be sometimes referred to as a normal pitch.

Note that the half pitch is an interval corresponding to a half of the full pitch. The device surface of the substrate W (W1, W2) is a surface on which an electronic circuit is formed, and will be referred to as a “front surface”. The surface of the substrate W without any electronic circuit will be referred to as a rear surface. The surface on the opposite side of the device surface is the rear surface.

FIG. 3(b) will now be referred to. The orientation converting unit 23 rotates the pair of horizontal holders 23B, 23C by 90 degrees about the horizontal axis AX2, to convert the orientation of the twenty-five substrates W1 from the horizontal to the vertical. FIG. 3(c) will now be referred to. The pusher mechanism 25 raises the pusher 25A to a position higher than the holders 23B, 23C in the orientation converting unit 23. The pusher 25A then receives twenty-five substrates W from the holders 23B, 23C. The twenty-five substrates W1 held on the pusher 25A face the left side Y. In FIG. 3(a) to 3(f), the arrow AR given to the substrate W indicates the direction of the device surface of the substrate W.

FIG. 3(d) will now be referred to. The pusher mechanism 25 also rotates the twenty-five substrates W by 180 degrees about the vertical axis AX3. As a result, the twenty-five substrates W1 are reversed and come to face the right side Y. Further, the positions of twenty-five reversed substrates W1 are shifted leftwards Y by a half pitch (e.g., 5 mm) from the position prior to the rotation. The holders 23B, 23C of the orientation converting unit 23 are also rotated by −90 degrees about the horizontal axis AX2 so that the next substrates W2 can be received. Then, the orientation converting unit 23 causes the holders 23B, 23C to receive the twenty-five substrates W2 of the second substrate group, having been transported by the substrate handling mechanism HTR. At this time, the twenty-five substrates W2 are in the horizontal orientation, with their device surfaces facing upwards. The orientation converting unit 23 and the pusher mechanism 25 are operated so as not to interfere with each other.

FIG. 3(e) will now be referred to. The pusher mechanism 25 lowers the pusher 25A holding the twenty-five substrates W1 of the first substrate group to the retracted position. The orientation converting unit 23 then converts the orientation of the twenty-five substrates W2 from the horizontal to the vertical. The twenty-five substrates W2 after the orientation conversion comes to face the left side Y. FIG. 3(f) will now be referred to. The pusher mechanism 25 then raises the pusher 25 A holding the twenty-five substrates W2 of the second substrate group. With this, the pusher mechanism 25 receives the additional twenty-five substrates W2 from the orientation converting unit 23.

As a result, the pusher 25A comes to hold fifty substrates W (W1, W2) belonging to the first substrate group and the second substrate group. In the fifty substrates W, each one of the twenty-five substrates W1 and the twenty-five substrates W2 is positioned alternately. The fifty substrates W are arranged at a half pitch (e.g., at an interval of 5 mm). The twenty-five substrates W1 face in the direction opposite to the direction to which the twenty-five substrates W2 face. Thus, the fifty substrates W are arranged face-to-face. That is, two device surfaces (or two rear surfaces) of two adjacent substrates W1, W2 face each other.

The pusher mechanism 25 then moves the pusher 25A holding the fifty substrates W along the rail 25D, to a substrate delivery position PP below a pair of chucks 29, 30 of the transporting mechanism WTR.

### 4. Processing Block 7

The processing block 7 is positioned adjacently to the transfer block 5. The processing block 7 is disposed on the rear side X of the transfer block 5. The processing block 7 includes a batch processing area R1, a batch substrate transporting area R2, an orientation converting area R3, a single-wafer transporting area R4, and a single-wafer processing area R5. The substrate processing apparatus 1 also includes a buffering unit 27 on which the substrate W is placed. The buffering unit 27 corresponds to the substrate placing unit according to the present invention.

### 4-1. Batch Processing Area R1

The batch processing area R1 is positioned adjacently to the batch substrate transporting area R2, the orientation converting area R3, and the single-wafer processing area R5. The batch processing area R1 extends in a direction separating from the transfer block 5 (rearwards X).

In the batch processing area R1, the six batch processing baths BT1 to BT6 are provided, for example. The six batch processing baths BT1 to BT6 are arranged in a row in the front-back direction X in which the batch processing area R1 extends. The number of batch processing baths is not limited to six, and may be any number more than one.

In each of the six batch processing baths BT1 to BT6, a plurality of substrates W are immersed as a batch. The six batch processing baths BT1 to BT6 include, for example, four chemical liquid processing baths BT1 to BT4 and two water cleaning processing baths BT5, BT6. Specifically, the two chemical liquid processing baths BT1, BT2 and the water cleaning processing bath BT5 constitute one set. The two chemical liquid processing baths BT3, BT4 and the water cleaning processing bath BT6 constitute another set.

Each of the four chemical liquid processing baths BT1 to BT4 performs an etching process using a chemical liquid. As the chemical liquid, for example, phosphoric acid is used. The chemical liquid processing bath BT1 stores therein a chemical liquid supplied from a chemical liquid ejection pipe, not illustrated. The chemical liquid ejection pipe is provided on the inner wall of the chemical liquid processing bath BT1. Each of the three chemical liquid processing baths BT2 to BT4 has the same configuration as the chemical liquid processing bath BT1.

Each of the two water cleaning processing baths BT5, BT6 performs a pure water cleaning process, for cleaning the chemical liquid attached to the plurality of substrates W with pure water. As the pure water, deionized water (DIW) is used, for example. Each of the two water cleaning processing baths BT5, BT6 stores therein pure water supplied from a cleaning liquid ejection pipe, not illustrated. The cleaning liquid ejection pipe is provided on the inner wall of each of the water cleaning processing baths BT5, BT6.

The six batch processing baths BT1 to BT6 are provided with six lifters LF1 to LF6, respectively. For example, the lifter LF1 holds a plurality of vertically oriented substrates W that are arranged at a predetermined interval (half pitch). Furthermore, the lifter LF1 raises and lowers the plurality of substrates W to and from a processing position inside the batch processing bath BT1 (chemical liquid processing bath) and a delivery position above the batch processing bath BT1. The other five lifters LF2 to LF6 have the same configurations as the lifter LF1.

### 4-2. Batch Substrate Transporting Area R2

The batch substrate transporting area R2 is positioned adjacently to the transfer block 5, the batch processing area R1, and the orientation converting area R3. The batch substrate transporting area R2 is provided along the batch processing area R1. One end of the batch substrate transporting area R2 extends up to the transfer block 5, and the other end extends in a direction separating from the transfer block 5 (rearwards X). The batch substrate transporting area R2 extends in parallel with the batch processing area R1.

The batch substrate transporting area R2 includes the transporting mechanism (robot) WTR. In other words, in the batch substrate transporting area R2, the transporting mechanism WTR is provided. The transporting mechanism WTR transports a plurality of (e.g., fifty) substrates W in the vertical orientation as a batch, between the substrate delivery position PP defined in the transfer block 5, the six batch processing baths BT1 to BT6, for example, and the second orientation converting mechanism 35 (lifter LF9). When the transporting mechanism WTR passes across the second orientation converting mechanism 35, the transporting mechanism WTR passes above a horizontally moving unit 95 included in an orientation converting unit 63, which will be described later.

The transporting mechanism WTR includes a pair of chucks 29, 30 and a guide rail 33. Each of the chucks 29, 30 includes, for example, fifty holding grooves for holding fifty substrates W. Each of the two chucks 29, 30 extends in parallel with the Y direction (FIG. 1) in plan view. The transporting mechanism WTR opens and closes the two chucks 29, 30. The transporting mechanism WTR moves the pair of chucks 29, 30 along the guide rail 33. The transporting mechanism WTR is driven by an electric motor.

### 4-3: Orientation Converting Area R3

The orientation converting area R3 is provided between the transfer block 5 and the batch processing area R1. The orientation converting area R3 is positioned between the batch substrate transporting area R2, and the single-wafer transporting area R4 and the single-wafer processing area R5. That is, the orientation converting area R3 is positioned adjacently to the transfer block 5, the batch processing area R1, the batch substrate transporting area R2, the single-wafer transporting area R4, and the single-wafer processing area R5.

In the orientation converting area R3, the second orientation converting mechanism 35 is provided. The second orientation converting mechanism 35 converts the plurality of substrates W having been applied with a batch process from the vertical orientation to the horizontal orientation. Details of the second orientation converting mechanism 35 will be described later.

### 4-4. Single-Wafer Transporting Area R4

The single-wafer transporting area R4 is positioned adjacently to the transfer block 5, the orientation converting area R3, and the single-wafer processing area R5. The single-wafer transporting area R4 is also provided on the opposite side of the batch substrate transporting area R2, with respect to the orientation converting area R3.

In the single-wafer transporting area R4, a center robot CR is provided. The center robot CR can transport one substrate W in the horizontal orientation at a time between the second orientation converting mechanism 35, the single-wafer processing chambers SW1, SW2 (to be described later) and the buffering unit 27. Around the center robot CR, the transfer block 5, the second orientation converting mechanism 35, and the single-wafer processing chambers SW1, SW2 can be disposed. As a result, because the distance by which the substrate W is transported by the center robot CR can be reduced, the substrate W can be transported efficiently.

The center robot CR includes two hands 37A, 37B, two articulated arms 39A, 39B, and a lifting stage 41. Each of the two hands 37A and 37B holds one substrate W in a horizontal orientation. Each of the two hands 37A and 37B is capable of moving horizontally. Each of the two articulated arms 39A, 39B is configured as, for example, a SCARA arm.

A distal end of the articulated arm 39A supports the hand 37A, and a distal end of the articulated arm 39B supports the hand 37B. The articulated arm 39A moves the hand 37A in the horizontal directions (the front-back direction X and the width direction Y), and the articulated arm 39B moves the hand 37B in the horizontal directions.

The lifting stage 41 supports the proximal end of each of the two articulated arms 39A, 39B. The lifting stage 41 is configured to be extendable in the up-and-down directions. The lifting stage 41 thus raises and lowers the two hands 37A, 37B and the two articulated arms 39A, 39B. The horizontal position of the lifting stage 41 is fixed, and does not move. With this, for example, it is possible to shorten the distance by which the substrate W is transported as the result of horizontal movement of the lifting stage 41. Furthermore, the movement of the lifting stage 41 can be omitted.

The buffering unit 27 is disposed in a manner straddling across the transfer block 5 and the single-wafer transporting area R4. That is, the buffering unit 27 is provided at the boundary between the transfer block 5 and the single-wafer transporting area R4. The buffering unit 27 may also be provided only in the transfer block 5 or the single-wafer transporting area R4. That is to say, the buffering unit 27 may be provided in a manner fixed at any one of the boundary between the transfer block 5 and the single-wafer transporting area R4, in the transfer block 5, and in the single-wafer transporting area R4. Although the center robot CR includes the two sets of hands 37A, 37B and the articulated arms 39A, 39B, the center robot CR may include one set or three or more sets of hands and articulated arms.

The buffering unit 27 includes a plurality of placing shelves. Each of the plurality of placing shelves is in a horizontal orientation. On each of the plurality of placing shelves, one substrate W can be placed. The buffering unit 27 places a plurality of substrates W in the horizontal orientation, with a predetermined interval (full pitch) therebetween in the vertical direction Z. That is, the plurality of placing shelves are arranged at a predetermined interval (full pitch) in the vertical direction Z. The buffering unit 27 is configured in such a manner that at least twenty-five substrates W, which are the number of substrates that can be transported by the substrate handling mechanism HTR, can be placed, for example. For example, the buffering unit 27 is enabled to place fifty substrates W thereon. The number of placing shelves in the buffering unit 27 may be two or more, and twenty four or less, as necessary.

### 4-5. Single-Wafer Processing Area R5

The single-wafer processing area R5 is positioned adjacently to the batch processing area R1, the orientation converting area R3, and the single-wafer transporting area R4. The single-wafer processing area R5 is provided on the opposite side of the transfer block 5, with the single-wafer transporting area R4 therebetween.

In the single-wafer processing area R5, a plurality of (e.g., two) single-wafer processing chambers SW1, SW2 are provided. The two single-wafer processing chambers SW1, SW2 are arranged along the width direction Y that is orthogonal to the front-back direction X in which the batch processing area R1 extends. Each of the single-wafer processing chambers SW1, SW2 processes one substrate W in the horizontal orientation at a time. The first single-wafer processing chamber SW1 is arranged on the right side Y of the orientation converting area R3. The second single-wafer processing chamber SW2 is disposed on the right side Y of the first single-wafer processing chamber SW1.

The single-wafer processing chambers SW1, SW2 may include a plurality of levels. For example, the six single-wafer processing chambers SW1, SW2 may be arranged by two in the width direction Y (horizontal direction), and three in the vertical direction Z. The number of the single-wafer processing chambers is not limited to two or six.

The first single-wafer processing chamber SW1 includes, for example, a rotating processing unit 45 and a nozzle 47. The rotating processing unit 45 includes a spin chuck that holds one horizontally oriented substrate W, and an electric motor that rotates the spin chuck about a vertical axis passing through the center of the substrate W. The spin chuck may hold the bottom surface of the substrate W by vacuum suctioning. The spin chuck may also include three or more chuck pins that grip the outer edge of the substrate W.

The nozzle 47 supplies a processing liquid onto the substrate W held by the rotating processing unit 45. The nozzle 47 is moved across a standby position away from the rotating processing unit 45 and a supply position above the rotating processing unit 45. As the processing liquid, for example, pure water (DIW) and isopropyl alcohol (IPA) are used. In the single-wafer processing chamber SW1, for example, after the substrate W is subjected to the cleaning process with the pure water, a liquid film of IPA may be formed on the top surface of the substrate W.

The single-wafer processing chamber SW2 performs, for example, a drying process using a supercritical fluid. As the fluid, carbon dioxide is used, for example. The single-wafer processing chamber SW2 includes a chamber body (container) 48, a support tray, and a lid. The chamber body 48 has an internal processing space, an opening through which the substrate W is inserted into the processing space, a supply port, and an exhaust port. The substrate W is housed in the processing space, in a manner supported on the support tray. The lid closes the opening of the chamber body 48. For example, in the single-wafer processing chamber SW2, the fluid is changed to the supercritical state, and the supercritical fluid is supplied into the processing space of the chamber body 48 through the supply port. At this time, the air in the processing space of the chamber body 48 is exhausted from the exhaust port. With the supercritical fluid supplied to the processing space, the substrate W is subjected to the drying process.

The supercritical state is achieved by setting the fluid to the critical temperature and the critical pressure unique to the fluid. Specifically, when carbon dioxide is used as the fluid, the critical temperature is 31° C., and the critical pressure is 7.38 MPa. By performing the drying process on the substrate W with the supercritical fluid, it is possible to suppress collapses of the pattern having been formed on the substrate W.

### 5. Control Unit

The substrate processing apparatus 1 includes a control unit 59 and a storage unit (not illustrated). The control unit 59 controls each component included in the substrate processing apparatus 1. The control unit 59 includes one or more processors such as a central processing unit (CPU). The storage unit includes at least one of a read-only memory (ROM), a random-access memory (RAM), and a hard disk, for example. The storage unit stores therein a computer program required in controlling each of the components included in the substrate processing apparatus 1.

### 6. Second Orientation Converting Mechanism

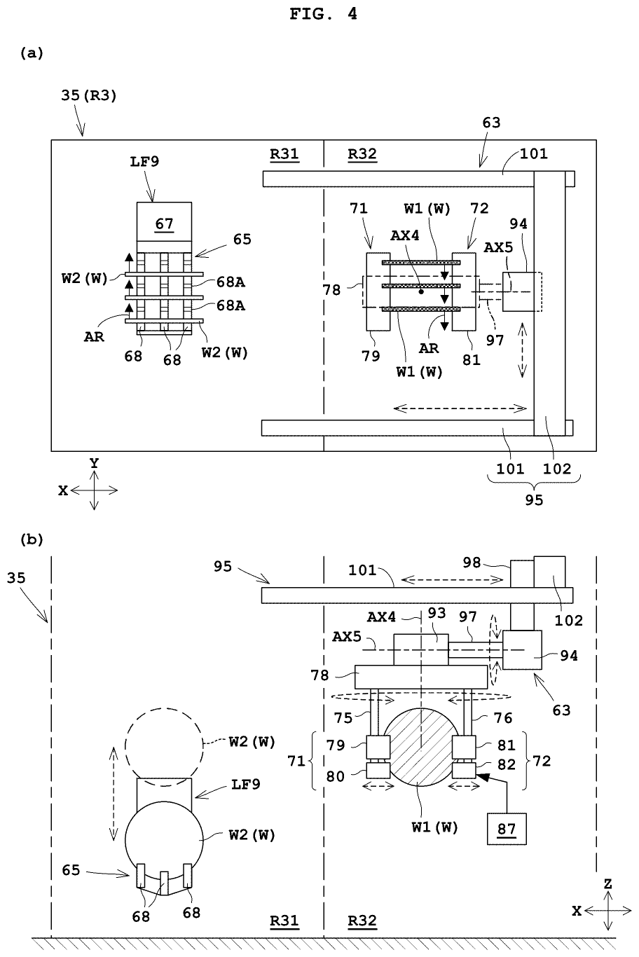

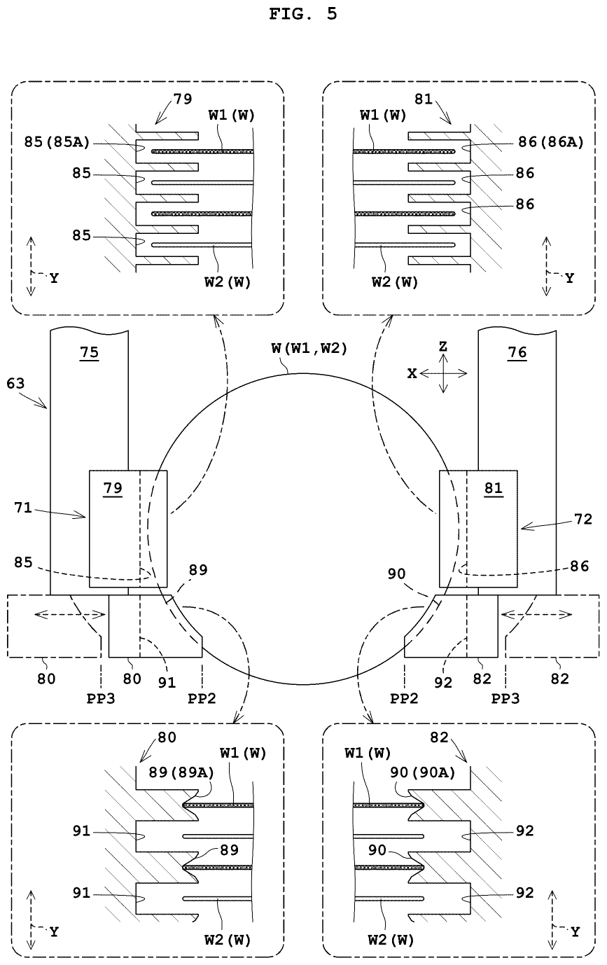

FIG. 4(a) is a plan view of the second orientation converting mechanism 35. FIG. 4(b) is a front view of the second orientation converting mechanism 35. FIG. 5 is a front view for explaining two chucks 71, 72 (horizontal holders 79, 81 and vertical holders 80, 82) of the orientation converting unit 63.

The second orientation converting mechanism 35 includes a substrate standby area R31 and an orientation conversion executing area R32. The substrate standby area R31 and the orientation conversion executing area R32 are arranged along the front-back direction X in which the batch processing area R1 or the six batch processing baths BT1 to BT6 extend.

The second orientation converting mechanism 35 includes a lifter LF9 and the orientation converting unit 63. In the substrate standby area R31, the lifter LF9 is provided. In the orientation conversion executing area R32, the orientation converting unit 63 is provided. The lifter LF9 and the orientation converting unit 63 will now be described in detail.

### 6-1. Lifter LF9

The lifter LF9 holds a plurality of (e.g., fifty) substrates W transported by the transporting mechanism WTR, in the vertical orientation. The lifter LF9 includes a substrate holding unit 65, and a lifting unit 67 that raises and lowers the substrate holding unit 65 in the vertical direction Z. The substrate holding unit 65 corresponds to a substrate holding unit according to the present invention.

The substrate holding unit 65 holds, for example, fifty substrates W that are arranged at a predetermined interval (for example, half pitch), from below. The substrate holding unit 65 includes, for example, three holding members 68 each extending in the Y direction. To hold fifty substrates W, each of the three holding members 68 includes the same number of (fifty) holding grooves 68A as the number of substrates W.

The rear end of each of the holding grooves 68A has a V shape. The lifting unit 67 raises and lowers the substrate holding unit 65. The lifting unit 67 includes, for example, an electric motor or an air cylinder.

The lifter LF9 (substrate holding unit 65) and the six batch processing baths BT1 to BT6 are linearly arranged in the front-back direction X so as to enable the transporting mechanism WTR to transport fifty substrates W linearly.

### 6-2. Orientation Converting Unit

The orientation converting unit 63 receives the plurality of substrates W from the substrate holding unit 65, and converts the orientation of the plurality of substrates W from the vertical to the horizontal. The orientation converting unit 63 includes two chucks 71, 72, two arms 75, 76, and an arm support 78.

The orientation converting unit 63 receives a plurality of (e.g., twenty-five) substrates W from the substrate holding unit 65 using the two chucks 71, 72 in the substrate standby area R31, and converts the orientation of the plurality of substrates W from the vertical to the horizontal, using a vertically rotating unit 94 provided in the orientation conversion executing area R32. This operation will now be explained specifically.

The two chucks 71, 72 hold a plurality of (e.g., twenty-five) substrates W. The first chuck 71 includes a first horizontal holder 79 and a first vertical holder 80. The second chuck 72 includes a second horizontal holder 81 and a second vertical holder 82. Each of the two horizontal holders 79, 81 and the two vertical holders 80, 82 is provided in a manner extending in a direction in which the plurality of substrates W is aligned.

The two horizontal holders 79, 81 house two side portions facing each other in the radial direction of each substrate W in the plurality of substrates W. When the plurality of substrates W are in the horizontal orientation, plurality of substrates W are placed on the two horizontal holders 79, 81 at a predetermined interval (for example, half pitch). The two vertical holders 80, 82 house two side portions of each substrate W in the plurality of substrates W. The two vertical holders 80, 82 are provided below the horizontal holders 79, 81 when the plurality of substrates W is in the vertical orientation. The two vertical holders 80, 82 hold the plurality of substrates W in the vertical orientation when the plurality of substrates W is in the vertical orientation. When the plurality of substrates W held by the two vertical holders 80, 82 are in the vertical orientation, the two horizontal holders 79, 81 are disposed in the horizontal direction XY with the plurality of substrates W nipped therebetween. Similarly, when the substrates W are in the vertical orientation, the two vertical holders 80, 82 are disposed in the horizontal direction XY with the plurality of substrates W nipped therebetween.

FIG. 5 will now be referred to. The two horizontal holders 79, 81 include a plurality of pairs (e.g., fifty pairs) of horizontal setting guide grooves 85, 86, respectively. The fifty first horizontal setting guide grooves 85 are provided to the horizontal holder 79. The fifty second horizontal setting guide grooves 86 are provided to the horizontal holder 81. For example, the two horizontal setting guide grooves 85A, 86A are positioned facing each other. When the plurality of substrates W are in the vertical orientation, each of the plurality of pairs of horizontal setting guide grooves 85, 86 serves a function similar to that of passing grooves 91, 92 to be described later.

The two horizontal holders 79, 81 may also include, for example, twenty-five pairs of horizontal setting guide grooves 85, 86. The number of pairs of the horizontal setting guide grooves 85, 86 is not limited to fifty pairs or twenty-five pairs. The number of pairs of the holding grooves 89, 90 and the passing grooves 91, 92 to be described later is also not limited to twenty-five pairs.

The two vertical holders 80, 82 include a plurality of pairs (e.g., twenty-five pairs) of holding grooves 89, 90 and a plurality of pairs (e.g., twenty-five pairs) of passing grooves 91, 92. Each of the plurality of pairs of holding grooves 89, 90 holds one substrate W. Each of the plurality of pairs of passing grooves 91, 92 allows one substrate W to pass therethrough. Each of the plurality of pairs of holding grooves 89, 90 and the plurality of pairs of passing grooves 91, 92 is arranged alternately. The two holding grooves 89A, 90A are positioned facing each other.

The twenty-five holding grooves 89 and the twenty-five passing grooves 91 are provided to the first vertical holder 80. Each of the twenty-five holding grooves 89 and the twenty-five passing grooves 91 is disposed alternately. The twenty-five holding grooves 90 and the twenty-five passing grooves 92 are provided in the second vertical holder 82. Each of the twenty-five holding grooves 90 and the twenty-five passing grooves 92 is disposed alternately. The rear end of each of the holding grooves 89, 90 has a V-shape cross section. Therefore, each of the holding grooves 89, 90 can hold one substrate W in the vertical orientation. With this, the substrates W are prevented from falling over substrates W adjacent thereto.

As illustrated in FIG. 4(b), the first arm 75 supports the first horizontal holder 79 and the first vertical holder 80. The second arm 76 supports the second horizontal holder 81 and the second vertical holder 82. The arm support 78 supports the upper end (base end) of each of the two arms 75, 76. The arm support 78 and the two arms 75, 76 together form a C shape or a U shape.

The arm support 78 is disposed on the opposite side of the two vertical holders 80, 82, with the two horizontal holders 79, 81 therebetween. Therefore, the arm support 78 and the like support the two horizontal holders 79, 81 and the two vertical holders 80, 82 from the opposite side of the two vertical holders 80, 82, with the two horizontal holders 79, 81 therebetween.

Further, as indicated by a solid line and an alternate long and short dash line in FIG. 5, the two vertical holders 80, 82 are configured to open and to close in the horizontal directions. That is, the orientation converting unit 63 includes an opening/closing unit 87 (see FIG. 4). The opening/closing unit 87 includes, for example, an electric motor or an air cylinder. The opening/closing unit 87 moves the two vertical holders 80, 82 linearly between a holding position PP2 with a narrower space between the two vertical holders 80, 82 so that the two vertical holders 80, 82 hold the substrate W, and a delivery position PP3 with a wider space between the two vertical holders 80, 82 so that the substrates W are passed between the two vertical holders 80, 82.

The two vertical holders 80, 82 at the holding position PP2 are closed. For example, when the plurality of substrates W are in the vertical orientation, the space between the two vertical holders 80, 82 is set narrower. By being moved to the holding position PP2 by the opening/closing unit 87, the two vertical holders 80, 82 hold the plurality of substrates W in the vertical orientation held by the substrate holding unit 65, and the two horizontal holders 79, 81 house the plurality of substrates W held by the two vertical holders 80, 82. At the delivery position PP3, the two vertical holders 80, 82 are open. For example, when the vertically rotating unit 94, to be described later, rotates the orientation of the substrate W from the vertical to the horizontal, the opening/closing unit 87 moves the two vertical holders 80, 82 to the delivery position PP3. In other words, when the plurality of substrates W is in the horizontal orientation, the space between the two vertical holders 80, 82 is set wider.

The orientation converting unit 63 includes a horizontally rotating unit 93, a vertically rotating unit 94, a horizontally moving unit 95, a rotating shaft 97, and a vertical arm 98. The horizontally rotating unit 93 supports the arm support 78 rotatably. While the two vertical holders 80, 82 are holding the substrate W in the vertical orientation, the horizontally rotating unit 93 rotates the two chucks 71, 72, the arm support 78, and the like about a rotation axis (vertical axis) AX4 orthogonal to the direction in which the substrates W are aligned. Each of the horizontally rotating unit 93 and the vertically rotating unit 94 includes an electric motor.

The distal end of the rotating shaft 97 is connected to the horizontally rotating unit 93. The base end of the rotating shaft 97 is connected rotatably to the vertically rotating unit 94. The rotating shaft 97 extends in the horizontal direction (front-back direction X). The rotating shaft 97 therefore has the horizontal axis AX5 as the central axis. The horizontal axis (central axis) AX5 is provided at a position higher than the vertically oriented substrates W held between the two vertical holders 80, 82. The vertically rotating unit 94 rotates the two chucks 71, 72, the arm support 78, and the like about the horizontal axis AX5 to rotate the substrates W from the vertical orientation to the horizontal orientation. The vertically rotating unit 94 is supported by the lower end of the vertical arm 98.

The horizontally moving unit 95 horizontally moves the two chucks 71, 72, the arm support 78, the opening/closing unit 87, the horizontally rotating unit 93, and the vertically rotating unit 94. The horizontally moving unit 95 horizontally moves the arm support 78 and the vertically rotating unit 94 across the substrate standby area R31 where the substrate holding unit 65 is provided, and the orientation conversion executing area R32 for converting the plurality of substrates W from the vertical orientation to the horizontal orientation.

The horizontally moving unit 95 is provided at a position higher than each of the vertically oriented substrate W held between the two vertical holders 80, 82. Therefore, the two chucks 71, 72 are thus suspended. Therefore, droplets attached to the substrates W are prevented from dripping and contaminating the moving units and the rotating units. In this manner, failures of the moving units and the rotating units are prevented, due to the contamination with the droplets.

The horizontally moving unit 95 includes an X-direction moving unit 101 and a Y-direction moving unit 102. The X-direction moving unit 101 moves the two chucks 71, 72, the arm support 78, and the like in the front-back direction X. The Y-direction moving unit 102 moves the two chucks 71, 72, the arm support 78, and the like in the width direction Y. Each of the two moving units 101,102 includes a linear actuator having an electric motor. In FIG. 4(a), the upper end of the vertical arm 98 is connected movably to the Y-direction moving unit 102. The Y-direction moving unit 102 moves the vertical arm 98 in the width direction Y.

### 7. Description of Operation

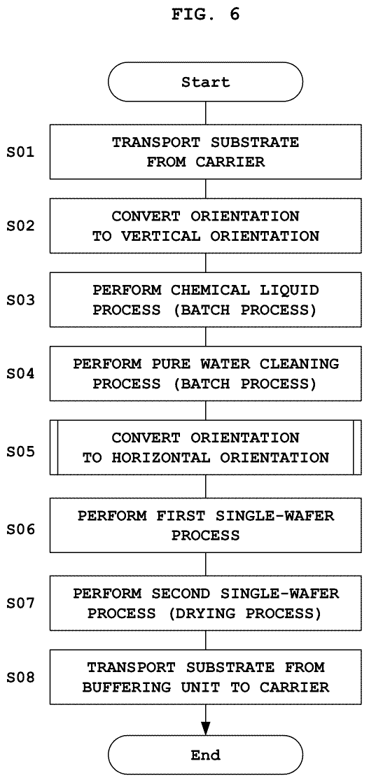

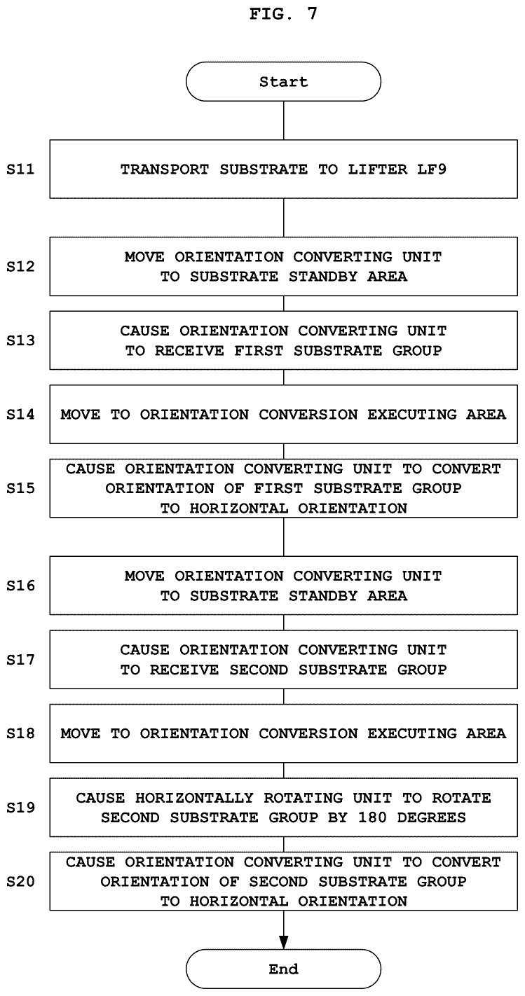

An operation of the substrate processing apparatus 1 will now be described with reference to the flowchart illustrated in FIGS. 6 and 7. FIG. 1 will now be referred to. An external transporting robot, not illustrated, transports two carriers C onto the loading ports 9 one after another.

### [Step S01] Transport Substrates From Carrier

The carrier transporting mechanism 11 in the stocker block 3 transports a first carrier C from the loading port 9 onto the shelf 13A. The substrate handling mechanism HTR in the transfer block 5 takes out twenty-five horizontally oriented substrates W1 from the first carrier C having been placed on the shelf 13A, and transports the twenty-five substrates W1 to the orientation converting unit 23. The carrier transporting mechanism 11 then transports the empty first carrier C to the shelf 13B. The carrier transporting mechanism 11 then transports the second carrier C from the loading port 9 onto the shelf 13A. The substrate handling mechanism HTR takes out the twenty-five horizontally oriented substrates W2 from the second carrier C having been placed on the shelf 13A, and transports the twenty-five substrates W2 to the orientation converting unit 23.

### [Step S02] Convert Orientation to Vertical Orientation

The fifty substrates W (W1, W2) corresponding to the two carriers C are transported to the orientation converting unit 23. As illustrated in FIG. 3(a) to 3(f), the orientation converting unit 23 and the pusher mechanism 25 align the fifty substrates W face-to-face at a half pitch (5 mm), and convert the orientation of the fifty substrates W from the horizontal orientation to the vertical orientation. The pusher mechanism 25 transports the fifty vertically oriented substrates W to the substrate delivery position PP established in the transfer block 5.

### [Step S03] Perform Chemical Liquid Process (Batch Process)

The transporting mechanism WTR receives the fifty vertically oriented substrates W from the pusher mechanism 25 at the substrate delivery position PP, and transports the fifty substrates W to any one of the four lifters LF1 to LF4 corresponding to the four respective chemical liquid processing baths BT1 to BT4. When the transporting mechanism WTR passes across the orientation converting area R3, the transporting mechanism WTR passes above the second orientation converting mechanism 35, for example, so as not to interfere with the second orientation converting mechanism 35.

For example, the transporting mechanism WTR transports the fifty substrates W onto the lifter LF1 of the chemical liquid processing bath BT1. The lifter LF1 receives the fifty substrates W at a position above the chemical liquid processing bath BT1. The lifter LF1 then immerses the fifty substrates W into phosphoric acid that is a chemical liquid in the chemical liquid processing bath BT1. With this, the fifty substrates W is subjected to the etching process. After the etching process, the lifter LF1 raises the fifty substrates W from the phosphoric acid in the chemical liquid processing bath BT1. Note that, when the fifty substrates W are transported to the lifter LF2 to LF4 of the other chemical liquid processing bath BT2 to BT4, too, the processing that is the same as that in the chemical liquid processing bath BT1 is performed.

### [Step S04] Perform Pure Water Cleaning Process (Batch Process)

The transporting mechanism WTR receives the fifty vertically oriented substrates W from the lifter LF1 (or the lifter LF2), for example, and transports the fifty substrates W to the lifter LF5 of the water cleaning processing bath BT5. The lifter LF5 receives the fifty substrates W at a position above the water cleaning processing bath BT5. The lifter LF5 then immerses the fifty substrates W in the pure water in the water cleaning processing bath BT5. In the manner described above, the cleaning process is performed on the fifty substrates W.

When the transporting mechanism WTR receives the fifty vertically oriented substrates W from one of the lifters LF3, LF4, the transporting mechanism WTR transports the fifty substrates W to the lifter LF6 of the water cleaning processing bath BT6. The lifter LF6 receives the fifty substrates W at a position above the water cleaning processing bath BT6. The lifter LF6 then immerses the fifty substrates W in the pure water in the water cleaning processing bath BT6.

### [Step S05] Convert to Horizontal Orientation

The second orientation converting mechanism 35 converts the orientation of the substrates W having been subjected to the cleaning process, from the vertical to the horizontal. At this time, there are the following problems. That is, when the orientation of the fifty substrates W arranged at a half pitch (5 mm interval) is converted as a batch, the hands 37A, 37B of the center robot CR may fail to go into the gap between two adjacent substrates W of the fifty substrates W appropriately.

In addition, when the substrates W aligned face-to-face are converted to the horizontal orientation, some of the substrates W have the device surfaces facing upwards, and the other substrates W have their device surfaces facing downwards. It is not preferable for the hands 37A, 37B of the center robot CR, for example, to come into contact with the device surface of a substrate W. It is also not preferable for the substrates W with their device surfaces facing different sides to be transported into the single-wafer processing chambers SW1, SW2.

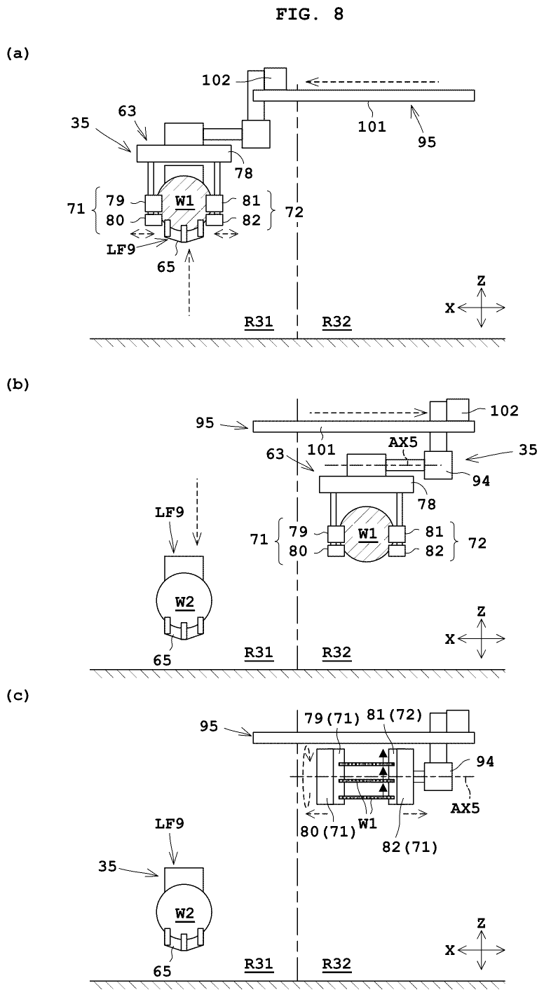

Therefore, in the present embodiment, the distance between the two adjacent substrates W is widened, and the device surface of each of the fifty substrates W is matched with those of the others. A specific description will be given with reference to the flowchart of FIG. 7, FIG. 1, and FIG. 8(a) to 11(c).

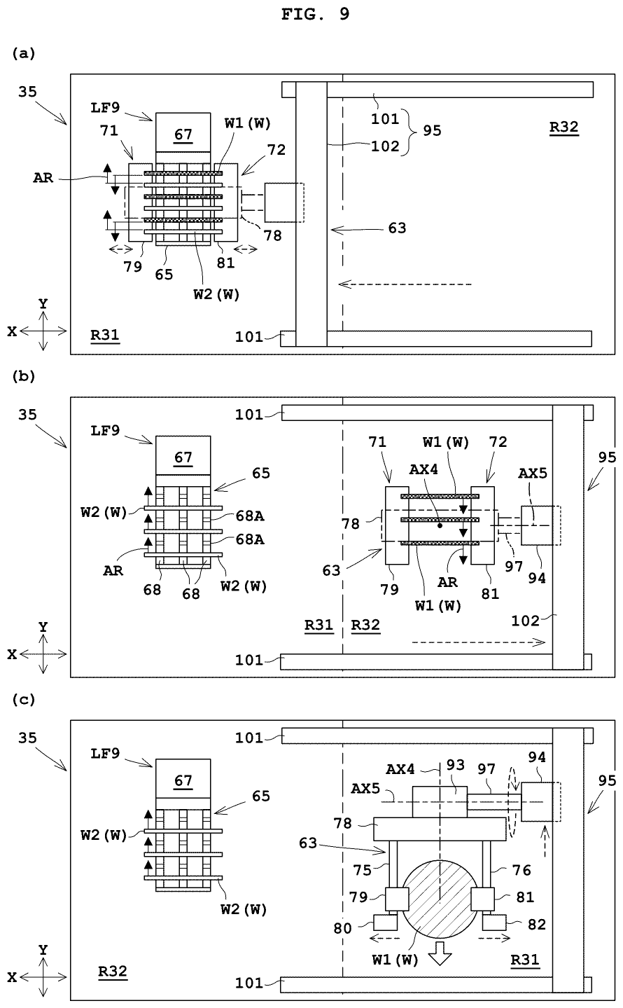

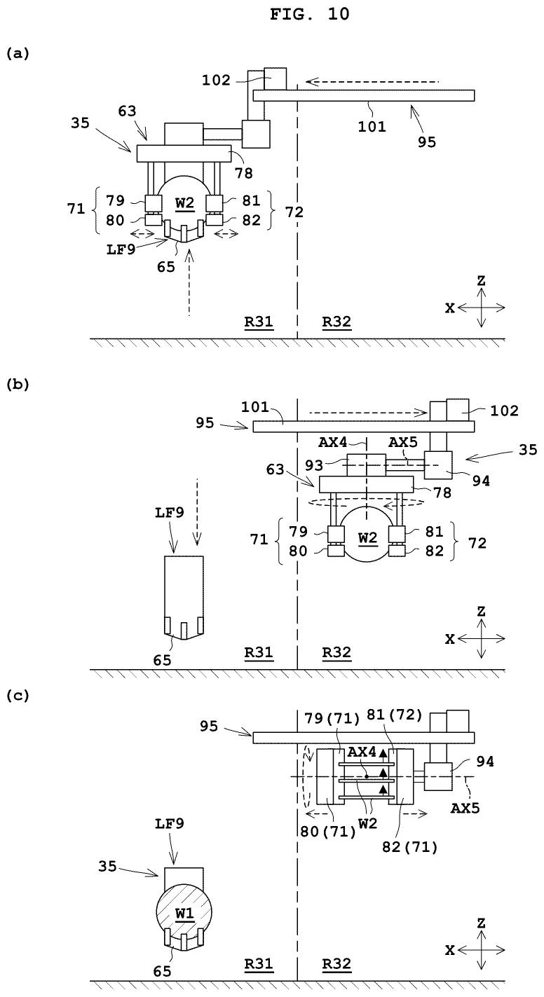

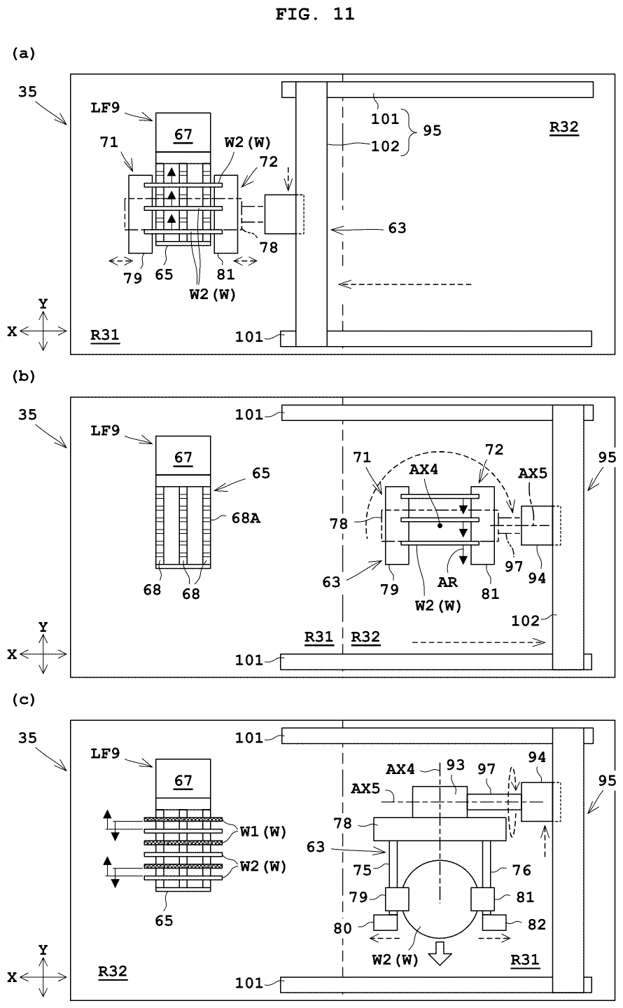

FIG. 8(a) to 8(c) and FIG. 10(a) to 10(c) are front views of the second orientation converting mechanism 35. FIG. 9(a) to 9(c) and FIG. 11(a) to 11(c) are plan views of the second orientation converting mechanism 35. For example, FIG. 9(a) corresponds to FIG. 8(a). FIG. 11(b) corresponds to FIG. 10(b).

### [Step S11] Transport Substrate To Lifter LF9

FIG. 1 will now be referred to. The transporting mechanism WTR transports fifty substrates W from one of the lifters LF5 and LF6 to the substrate holding unit 65 of the lifter LF9 of the second orientation converting mechanism 35. The substrate holding unit 65 of the lifter LF9 holds the fifty vertically oriented substrates W that are arranged face-to-face at a half pitch. The fifty substrates W are aligned in the width direction Y.

### [Step S12] Move Orientation Converting Unit to Substrate Standby Area

FIG. 8(a) and 9(a) will now be referred to. Once the substrate holding unit 65 holds the fifty vertically oriented substrates W, the horizontally moving unit 95 (mainly the X-direction moving unit 101) of the orientation converting unit 63 moves the two chucks 71, 72, the arm support 78, and the like from the orientation conversion executing area R32 to above the substrate holding unit 65 in the substrate standby area R31. The Y-direction moving unit 102 of the horizontally moving unit 95 moves the two chucks 71, 72, the arm support 78, and the like to a first substrate holding position. The first substrate holding position is a position where the twenty-five pairs of holding grooves 89, 90 can hold the twenty-five substrates W1 of the first substrate group.

The opening/closing unit 87 in the orientation converting unit 63 opens the two vertical holders 80, 82 by horizontally moving the vertical holders 80, 82 in the direction separating from each other (see the delivery position PP3 in FIG. 5).

### [Step S13] Cause Orientation Converting Unit to Receive First Substrate Group

When the opening/closing unit 87 moves the two vertical holders 80, 82 to the holding position PP2, the twenty-five pairs of holding grooves 89, 90 hold a first substrate sub-group (twenty-five substrates W1) having been arranged alternately in the fifty vertically oriented substrates W held by the substrate holding unit 65, and the two horizontal holders 79, 81 houses the first substrate subgroup (twenty-five substrates W1). This operation will now be explained specifically.

The substrate holding unit 65 is now holding fifty vertically oriented substrates W (W1, W2). The lifting unit 67 in the lifter LF9 then raises the substrate holding unit 65 to a higher position where the substrates W can be delivered. At this time, the fifty substrates W are passed between the two vertical holders 80, 82, and are housed in the fifty respective pairs of horizontal setting guide grooves 85, 86 of the two horizontal holders 79, 81.

The opening/closing unit 87 then closes the two vertical holders 80, 82 by horizontally moving the vertical holders 80, 82 in the direction of moving closer to each other (see the holding position PP2 in FIG. 5). As a result, the fifty vertically oriented substrates W held by the substrate holding unit 65 are housed in the twenty-five pairs of holding grooves 89, 90 and twenty-five pairs of passing grooves 91, 92 that are positioned alternately, as illustrated in two frames on the lower side of FIG. 5.

The lifting unit 67 in the lifter LF9 then lowers the substrate holding unit 65 to the lower standby position. As a result, the twenty-five substrates W1 belonging to the first substrate group are delivered to the orientation converting unit 63, while the twenty-five substrates W2 of the second substrate group are left in the substrate holding unit 65. That is, the orientation converting unit 63 holds and extracts the twenty-five substrates W1 of the first substrate group, the twenty-five substrates being aligned alternately among the fifty substrates W in the substrate holding unit 65, using the twenty-five pairs of holding grooves 89, 90. The plurality of substrates W1 belonging to the first substrate group will be referred to as a first substrate subgroup. The plurality of substrates W2 belonging to the second substrate group will be referred to as a second substrate subgroup.

The twenty-five substrates W1 having been alternately extracted are now aligned at a full pitch. The twenty-five substrates W2 left in the substrate holding unit 65 are also arranged at a full pitch. The twenty-five substrates W2 left in the substrate holding unit 65 are kept in standby.

### [Step S14] Move to Orientation Conversion Executing Area

FIG. 8(b) and 9(b) will now be referred to. The horizontally moving unit 95 (the X-direction moving unit 101 and the Y-direction moving unit 102) moves the two chucks 71, 72, the arm support 78, and the like, from above the substrate holding unit 65 in the substrate standby area R31 to a predetermined position in the orientation conversion executing area R32, while the two vertical holders 80, 82 are holding the twenty-five substrates W1. That is, the orientation converting unit 63 transports the twenty-five vertically oriented substrates W1 belonging to the first substrate group to the orientation conversion executing area R32.

### [Step S15] Cause Orientation Converting Unit to Convert Orientation of First Substrate Group to Horizontal Orientation

FIG. 8(c) and 9(c) will now be referred to. In the orientation conversion executing area R32, the orientation converting unit 63 then converts the orientation of the twenty-five extracted substrates W1 to the horizontal orientation. Specifically, the vertically rotating unit 94 of the orientation converting unit 63 rotates the substrates W1, the two chucks 71, 72, and the arm support 78 by 90 degrees about the horizontal axis AX5 so that the two vertical holders 80, 82 face the center robot CR (see FIG. 1).

In this setting, the center robot CR is not capable of taking out the substrates W1 from the orientation converting unit 63. Therefore, the opening/closing unit 87 of the orientation converting unit 63 opens the two vertical holders 80, 82 by moving vertical holders 80, 82 horizontally in the direction separating from each other. That is, when the twenty-five substrates W1 having been converted into the horizontal orientation are to be placed on the two horizontal holders 79, 81, the opening/closing units 87 moves the two vertical holders 80, 82 to the delivery position PP3. As a result, the substrates W1 are allowed to pass between the two vertical holders 80, 82. The twenty-five substrates W1 are then placed on the twenty-five horizontal setting guide grooves 85, 86, respectively. Because the twenty-five substrates W1 are aligned at a full pitch, the center robot CR can take out the substrates W easily.

The center robot CR then takes out the substrates W1 one by one from the twenty-five horizontally orientated substrates W1 using the two hands 37A, 37B, while allowing the substrates W1 to pass between the two vertical holders 80, 82 having been moved to the delivery position PP3, and transports the substrates W1 having been taken out to the single-wafer processing chamber SW1.

### [Step S16] Move Orientation Converting Unit to Substrate Standby Area

FIG. 10(a) and 11(a) will now be referred to. After all of the twenty-five substrates W1 are transported from the orientation converting unit 63, the horizontally moving unit 95 (mainly the X-direction moving unit 101) moves the two chucks 71, 72, the arm support 78, and the like from the orientation conversion executing area R32 to above the substrate holding unit 65 in the substrate standby area R31. The Y-direction moving unit 102 in the horizontally moving unit 95 moves the two chucks 71, 72, the arm support 78, and the like to a second substrate holding position. The second substrate holding position is a position where the twenty-five pairs of holding grooves 89, 90 can hold the twenty-five substrates W2 of the second substrate group.

The opening/closing unit 87 in the orientation converting unit 63 opens the two vertical holders 80, 82 by horizontally moving the vertical holders 80, 82 in the direction separating from each other (see the delivery position PP3 in FIG. 5).

### [Step S17] Cause Orientation Converting Unit to Receive Second Substrate Group

The substrate holding unit 65 is holding twenty-five substrates W2 of the second substrate group in the vertical orientation. The lifting unit 67 in the lifter LF9 raises the substrate holding unit 65 to a higher position where the substrates W2 can be delivered. At this time, the twenty-five substrates W2 are passed between the two vertical holders 80, 82, and are housed in the twenty-five respective pairs of horizontal setting guide grooves 85, 86, out of the fifty pairs of horizontal setting guide grooves 85, 86.

The opening/closing unit 87 then closes the two vertical holders 80, 82 by horizontally moving the vertical holders 80, 82 in the direction of moving closer to each other (see the holding position PP2 in FIG. 5). As a result, the twenty-five substrates W2 held in the vertical orientation by the substrate holding unit 65 are housed in the twenty-five respective pairs of holding grooves 89, 90.

The lifting unit 67 in the lifter LF9 then lowers the substrate holding unit 65 to the lower standby position. As a result, the twenty-five substrates W2 belonging to the second substrate group are delivered to the orientation converting unit 63. In other words, the orientation converting unit 63 holds and receives the twenty-five substrates W2 of the second substrate group from the substrate holding unit 65, using the twenty-five pairs of holding grooves 89, 90.

### [Step S18] Move to Orientation Conversion Executing Area

FIG. 10(b) and 11(b) will now be referred to. The horizontally moving unit 95 (the X-direction moving unit 101 and the Y-direction moving unit 102) moves the two chucks 71, 72, the arm support 78, and the like, from above the substrate holding unit 65 in the substrate standby area R31 to a predetermined position in the orientation conversion executing area R32, while the two vertical holders 80, 82 are holding the twenty-five substrates W2. That is, the orientation converting unit 63 transports the twenty-five vertically oriented substrates W2 to the orientation conversion executing area R32.

### [Step S19] Cause Horizontally Rotating Unit to Rotate Second Substrate Group by 180 Degrees

In the orientation conversion executing area R32, the horizontally rotating unit 93 in the orientation converting unit 63 rotates the substrates W2 in the vertical orientation, the arm support 78, and the like by 180 degrees about the rotation axis AX4. With this, the orientation of the device surfaces indicated by the arrows AR are rotated by 180 degrees from the left side Y to the right side Y. Therefore, the device surface of each of the substrates W2 faces upwards when the orientation is converted to the horizontal orientation.

### [Step S20] Cause Orientation Converting Unit to Convert Orientation of Second Substrate Group to Horizontal Orientation

FIG. 10(c) and 11(c) will now be referred to. The orientation converting unit 63 then converts the twenty-five substrates W2 being held to the horizontal orientation. Specifically, the vertically rotating unit 94 of the orientation converting unit 63 rotates the substrates W2, the two chucks 71, 72, and the arm support 78 by 90 degrees about the horizontal axis AX5 so that the two vertical holders 80, 82 face the center robot CR (see FIG. 1).

The opening/closing unit 87 in the orientation converting unit 63 then opens the two vertical holders 80, 82 by horizontally moving the vertical holders 80, 82 in the direction separating from each other (see the delivery position PP3 in FIG. 5). As a result, the substrates W2 are allowed to pass between the two vertical holders 80, 82. The twenty-five substrates W2 are placed in the twenty-five horizontal setting guide grooves 85, 86, respectively.

The center robot CR then takes out the substrates W2 one by one from the twenty-five horizontally orientated substrates W2 using the two hands 37A, 37B, while allowing the substrates W2 to pass through between the two vertical holders 80, 82 having been moved to the delivery position PP3, and transports the substrates W2 having been taken out to the single-wafer processing chamber SW1. As illustrated in FIGS. 10C and 11C, to the substrate holding unit 65 of the lifter LF9, the next fifty substrates W are transported by the transporting mechanism WTR.

### [Step S06] Perform First Single-Wafer Process

The description returns to the flowchart of FIG. 6. The center robot CR transports the substrates W (W1, W2) one by one from the orientation converting unit 63 to the first single-wafer processing chamber SW1, for example. In the first single-wafer processing chamber SW1, the rotating processing unit 45 rotates the substrate W, by holding the substrate W in such a manner that the device surface thereof facing upwards, and the pure water is supplied onto the device surface, via the nozzle 47. In the first single-wafer processing chamber SW1, IPA is supplied from the nozzle 47 onto the device surface (upper surface) of the substrate W, thereby replacing the pure water on the substrate W with the IPA.

[Step S07] Perform Second Single-Wafer Process (Drying Process)

The center robot CR then takes out the substrate W wetted with IPA from the first single-wafer processing chamber SW1, and transports the substrate W to the second single-wafer processing chamber SW2. The second single-wafer processing chamber SW2 performs the process of drying the substrate W, using carbon dioxide in the supercritical state (supercritical fluid). With the drying process using the supercritical fluid, collapses of the pattern on the pattern surface (device surface) of the substrate W is suppressed.

### [Step S08] Transport Substrate From Buffering Unit to Carrier

The center robot CR transports the substrate W having been subjected to the drying process from the second single-wafer processing chamber SW2 to any one of the placing shelves in the buffering unit 27.

When the substrates W1 corresponding to one lot (twenty-five) have been transported to the buffering unit 27, the substrate handling mechanism HTR transports the twenty-five substrates W1 as a batch, from the buffering unit 27 into the empty first carrier C having been placed on the shelf 13A. The carrier transporting mechanism 11 in the stocker block 3 then transports the first carrier C to the loading port 9.

When the substrates W2 corresponding to one lot have been placed on the buffering unit 27, the substrate handling mechanism HTR transports the twenty-five substrates W2 as a batch, from the buffering unit 27 into the empty second carrier C having been placed on the shelf 13A. The carrier transporting mechanism 11 in the stocker block 3 then transports the second carrier C to the loading port 9. An external transporting robot, not illustrated, transports two carriers C to the next destination one after another.

According to the present embodiment, the orientation converting area R3 (including the second orientation converting mechanism 35) is provided between the transfer block 5 and the batch processing area R1.

The single-wafer transporting area R4 is positioned adjacently to the transfer block 5 and the orientation converting area R3. Furthermore, the single-wafer processing area R5 (including a plurality of single-wafer processing chambers SW1, SW2) is positioned adjacently to the single-wafer transporting area R4. Furthermore, the position of the lifting stage 41 included in the center robot CR provided in the single-wafer transporting area R4 in the horizontal direction XY is fixed. Therefore, the transfer block 5, the second orientation converting mechanism 35, and the plurality of single-wafer processing chambers SW1, SW2 can be disposed around the center robot CR. As a result, because the distance by which the substrate W is transported by the center robot CR can be reduced, for example, the substrate W can be transported efficiently. Furthermore, the transporting mechanism WTR can transport a plurality of substrates W to and from the substrate delivery position PP in the transfer block 5, the six batch processing baths BT1 to BT6, and the second orientation converting mechanism 35. As a result, the throughput can be improved.

In addition, the second orientation converting mechanism 35 includes the substrate standby area R31 and the orientation conversion executing area R32 that are arranged along the front-back direction X in which the batch processing area R1 extends. In the substrate standby area R31, the substrate holding unit 65 configured to hold a plurality of vertically oriented substrates W transported by the transporting mechanism WTR is provided. In the orientation conversion executing area R32, the orientation converting unit 63 is provided. The orientation converting unit 63 includes the two chucks 71, 72 configured to hold the plurality of substrates W, the vertically rotating unit 94 that rotates the two chucks 71, 72 about the horizontal axis AX5, and the horizontally moving unit 95 configured to move the two chucks 71, 72 and the vertically rotating unit 94, to and from a position above the substrate holding unit 65 and a preset position in the orientation conversion executing area R32.

The orientation converting unit 63 receives a plurality of substrates W from the substrate holding unit 65 using the two chucks 71, 72 in the substrate standby area R31, and converts the orientation of the plurality of substrates W from the vertical to the horizontal, using the vertically rotating unit 94 provided in the orientation conversion executing area R32.

As a result, in the width direction Y orthogonal to the front-back direction X in which the batch processing area R1 extends, the width of the orientation converting area R3 in which the second orientation converting mechanism 35 is disposed becomes smaller. Therefore, the width of the substrate processing apparatus 1 can be kept small.

Furthermore, the single-wafer processing area R5 is provided on the opposite side of the transfer block 5, with the single-wafer transporting area R4 therebetween. The transfer block 5 has a relatively large width in the width direction Y orthogonal to the front-back direction X in which the batch processing area R1 extends. Because the single-wafer processing area R5 is disposed in a manner facing the transfer block 5, the width of the substrate processing apparatus 1 can be kept small.

### Second Embodiment

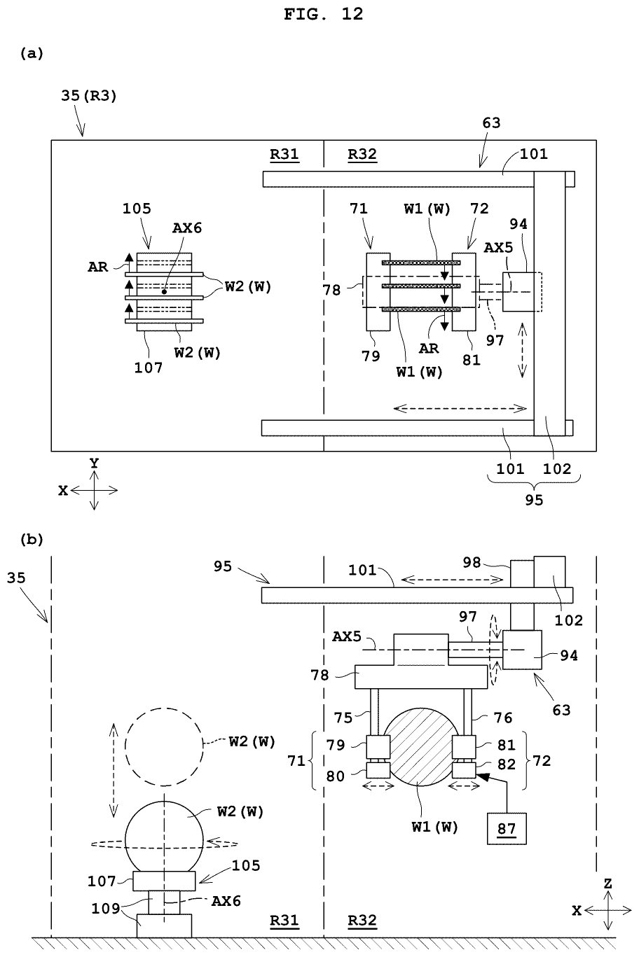

A second embodiment according to the present invention will now be described with reference to drawings. Note that redundant descriptions with those in the first embodiment will be omitted. FIG. 12(a) is a plan view illustrating the second orientation converting mechanism 35 according to the second embodiment. FIG. 12(b) is a front view of FIG. 12(a).

In the first embodiment, the second orientation converting mechanism 35 includes the lifter LF9 and the orientation converting unit 63 that includes the horizontally rotating unit 93. In this regard, the second orientation converting mechanism 35 according to the second embodiment includes a pusher mechanism 105 and an orientation converting unit 63 not including the horizontally rotating unit 93.

The pusher mechanism 105 holds a plurality of (e.g., fifty) substrates W transported by the transporting mechanism WTR in the vertical orientation. The pusher mechanism 105 includes a pusher 107 and a rotating lift 109. The pusher 107 corresponds to a substrate holding unit according to the present invention.

The pusher 107 holds, for example, fifty substrates W that are arranged at a predetermined interval (for example, half pitch), from below. To hold fifty substrates W, the pusher 107 includes the same number of (fifty) holding grooves (not illustrated) as the number of substrates W.

The rear end of each of the holding grooves of the pusher 107 has a V shape. The rotating lift 109 raises and lowers the pusher 107, and rotates the pusher 107 about a vertical axis AX6. The rotating lift 109 includes, for example, one or more electric motors.

As illustrated in FIG. 12(b), the orientation converting unit 63 according to the second embodiment does not include the horizontally rotating unit 93, illustrated in FIG. 4(b). Therefore, the distal end of the rotating shaft 97 is fixed to the arm support 78.

An operation of the second orientation converting mechanism 35 according to the second embodiment will now be described with reference to the flowchart illustrated in FIG. 7. The second orientation converting mechanism 35 basically operates in accordance with the flowchart illustrated in FIG. 7. However, because the second orientation converting mechanism 35 according to the second embodiment does not include the horizontally rotating unit 93, step S19 illustrated in FIG. 7 is not performed. Instead, the pusher mechanism 105 rotates the twenty-five substrates W2 of the second substrate group about the vertical axis AX6.

In step S13 of FIG. 7, the orientation converting unit 63 holds and extracts the twenty-five substrates W1 aligned alternately, among the fifty substrates W in the substrate holding unit 65, using the two vertical holder 80, 82 (twenty-five pairs of holding grooves 89, 90).

The rotating lift 109 in the pusher mechanism 105 then rotates the twenty-five substrates W2 held by the pusher 107 by 180 degrees about the vertical axis AX6. As a result, once the orientation of the substrates W2 of the second substrate group is converted, it is possible to have the device surfaces facing upwards, in the same manner as the substrates W1 of the first substrate group. The vertical axis AX6 is set at the center of the fifty substrates W held by the pusher 107, in plan view. Having been rotated by 180 degrees, the positions of the substrates W2 are offset by a half pitch in the direction in which the substrates W are aligned. Therefore, the two vertical holders 80, 82 can hold the substrates W1 of the second substrate group at the same first substrate holding position allowing the twenty-five pairs of holding grooves 89, 90 to hold the substrates W1 of the first substrate group. The horizontally moving unit 95 may also be configured to move the two vertical holders 80, 82, and the like to each of the first substrate holding position and the second substrate holding position.

In step S17 of FIG. 7, the orientation converting unit 63 holds and transports twenty-five substrates W2 having been rotated by 180 degrees. In the second embodiment, step S19 in FIG. 7 is not performed.

According to the present embodiment, the rotating lift 109 in the pusher mechanism 105 rotates the pusher 107 about the vertical axis AX6. Therefore, it is possible for the orientation converting unit 63 not to include the horizontally rotating unit 93 according to the first embodiment, and to switch the front and the rear sides of the substrate W using the pusher 107. Therefore, it is possible to simplify the configuration of the orientation converting unit 63.

### Third Embodiment

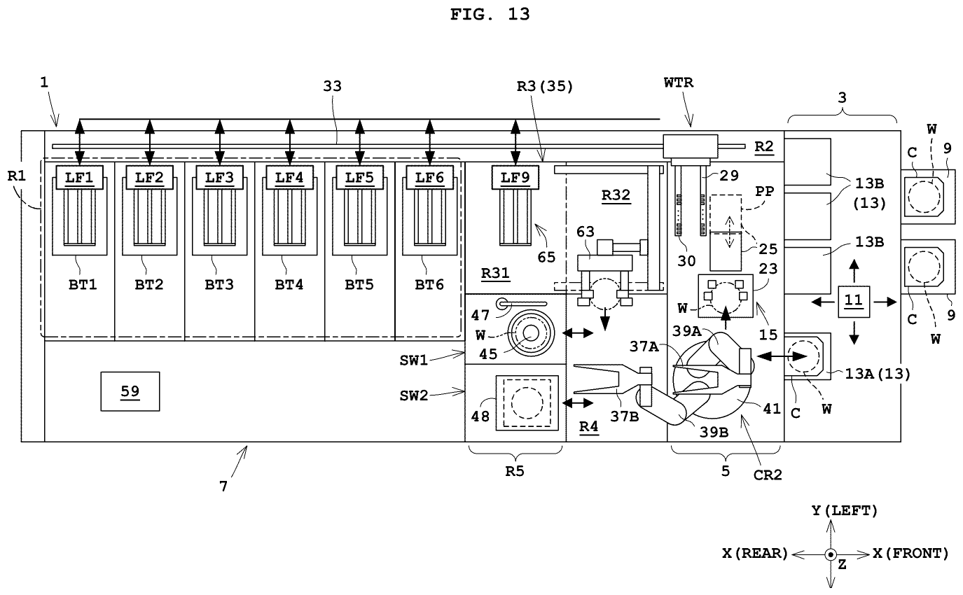

A third embodiment according to the present invention will now be described with reference to drawings. Note that redundant descriptions with those in the first and the second embodiments will be omitted. FIG. 13 is a plan view illustrating a schematic configuration of a substrate processing apparatus 1 according to the third embodiment.

In the first embodiment, the substrate processing apparatus 1 includes the substrate handling mechanism HTR, the center robot CR, and the buffering unit 27 (see FIG. 1). In this regard, in the third embodiment, the substrate processing apparatus 1 does not include the substrate handling mechanism HTR and the buffering unit 27. That is, a center robot CR2 also plays the role of the substrate handling mechanism HTR.

FIG. 13 will now be referred to. In the transfer block 5, the center robot CR2 is provided. The single-wafer transporting area R4 does not include the transporting robot including the center robot CR2. The center robot CR2 in the transfer block 5 has substantially the same configuration as the center robot CR according to the first embodiment. The center robot CR2 transports the substrates W to and from the carrier C having been placed on the shelf 13A, the first orientation converting mechanism 15, the second orientation converting mechanism 35 (orientation converting unit 63), and the plurality of single-wafer processing Chambers Sw1, Sw2.

For example, the center robot CR2 takes out one substrate W from the carrier C having been placed on the shelf 13A, using each of the hands 37A, 37B, and transports the one substrate W to the first orientation converting mechanism 15. The center robot CR2 also takes out one substrate W from the second orientation converting mechanism 35 using each of the hands 37A, 37B, and transports the one substrate W to the first single-wafer processing chamber SW1.

The center robot CR2 also takes out one substrate W from the first single-wafer processing chamber SW1, and transports the one substrate W to the second single-wafer processing chamber SW2. The center robot CR2 also takes out one substrate W from the second single-wafer processing chamber SW2, and returns the one substrate W to the carrier C having been placed on the shelf 13A.

According to the present embodiment, the orientation converting area R3 (including the second orientation converting mechanism 35) is provided between the transfer block 5 and the batch processing area R1.

The single-wafer transporting area R4 is positioned adjacently to the transfer block 5 and the orientation converting area R3. Furthermore, the single-wafer processing area R5 (including a plurality of single-wafer processing chambers SW1, SW2) is positioned adjacently to the single-wafer transporting area R4. Furthermore, the position of the lifting stage 41 of the center robot CR2 provided in the transfer block 5 in the horizontal direction XY is fixed. Therefore, the carrier C placed on the placing shelf 13A, the first orientation converting mechanism 15, the second orientation converting mechanism 35, and the plurality of single-wafer processing chambers SW1, SW2 can be disposed around the center robot CR2. As a result, because the distance by which the substrate W is transported by the center robot CR2 can be reduced, for example, the substrate W can be transported efficiently. Furthermore, the transporting mechanism WTR can transport a plurality of substrates W to and from the substrate delivery position PP in the transfer block 5, the six batch processing baths BT1 to BT6, for example, and the second orientation converting mechanism 35. In particular, the substrate W taken out from the single-wafer processing chamber SW2 can be transported directly to the carrier C on the placing shelf 13A. As a result, the throughput can be improved.

The present invention is not limited to the embodiments described above, and the following modifications are still possible.

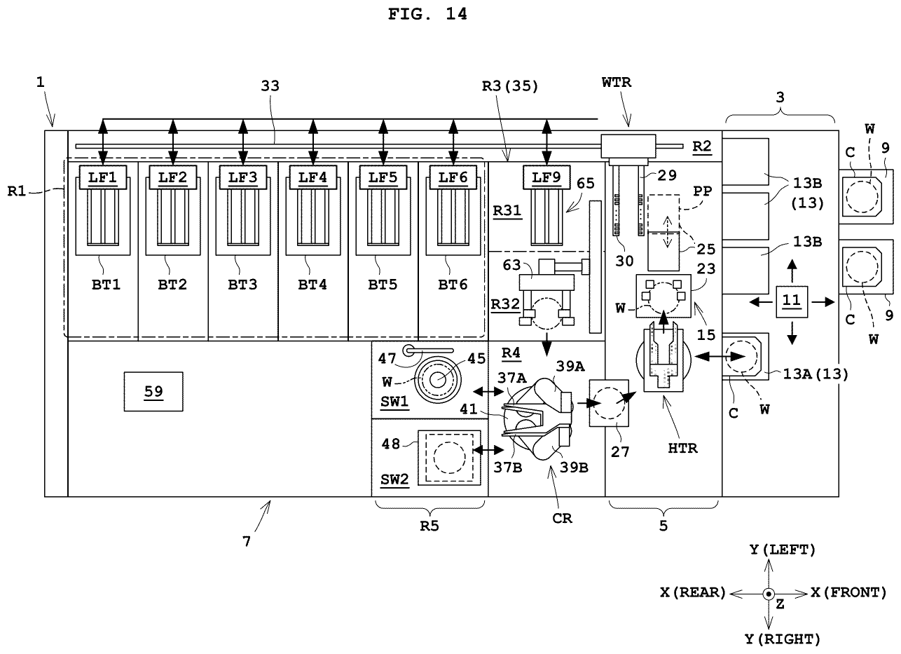

(1) In each of the embodiments described above, for example, in FIG. 1, the substrate standby area R31 for the second orientation converting mechanism 35 is positioned adjacently to the batch processing area R1, and the orientation conversion executing area R32 is positioned adjacently to the transfer block 5. In other words, the substrate standby area R31 and the orientation conversion executing area R32 of the second orientation converting mechanism 35 are arranged in the front-back direction X. In this regard, as illustrated in FIG. 14, the substrate standby area R31 and the orientation conversion executing area R32 may be disposed along the width direction Y.

In such a configuration, the orientation conversion executing area R32 is disposed on the left side Y of the single-wafer transporting area R4. The substrate standby area R31 is disposed on the left side Y of the orientation conversion executing area R32.

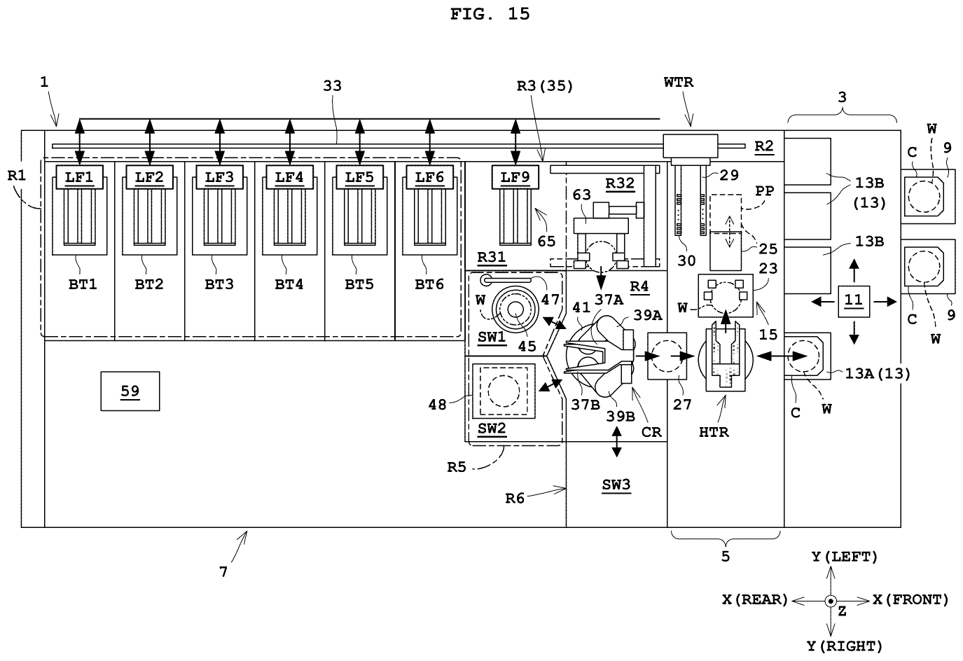

(2) In each of the embodiments and the modification (1) described above, the single-wafer processing area R5 (single-wafer processing chambers SW1, SW2) is provided on the opposite side of the transfer block 5, with the single-wafer transporting area R4 therebetween, and is positioned adjacently to the orientation converting area R3. In this regard, as illustrated in FIG. 15, the processing block 7 may further include a second single-wafer processing area R6 provided on the opposite side of the orientation converting area R3 with the single-wafer transporting area R4 disposed therebetween. The second single-wafer processing area R6 is provided with a third single-wafer processing chamber SW3 having a configuration similar to that of one of the single-wafer processing chambers SW1, SW2. The second single-wafer processing area R6 may include a plurality of third single-wafer processing chambers SW3 arranged along the vertical direction Z.

With this, because the single-wafer processing area becomes larger, a larger number of single-wafer processing chambers can be disposed. In other words, in FIG. 15, because the single-wafer processing chamber SW3 is provided, the number of single-wafer processing chambers can be increased. Therefore, it is possible to improve the throughput of the single-wafer process.

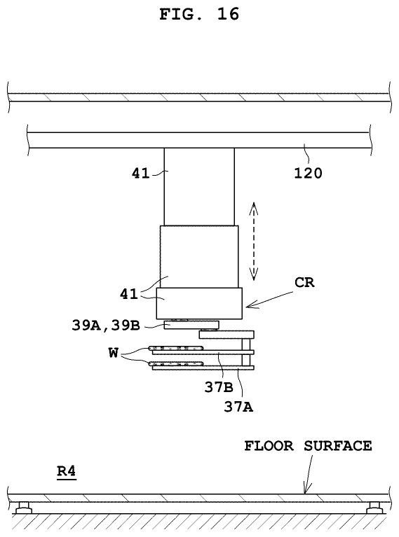

(3) In each of the embodiments and the modifications described above, the lifting stage 41 of the center robot CR is provided on the floor surface of the single-wafer transporting area R4. Alternatively, the center robot CR, that is, the lifting stage 41 may be suspended at the position above the single-wafer transporting area R4. At this upper position, the position of the lifting stage 41 in the horizontal direction XY is fixed. As illustrated in FIG. 16, the upper end (base end) of the lifting stage 41 is fixed, without moving in the horizontal direction XY, to a support frame 120 provided to the ceiling above the single-wafer transporting area R4. The proximal ends of the articulated arms 39A, 39B are provided to the bottom of the lifting stage 41. The two hands 37A, 37B are provided at the distal ends (and below) of the respective articulated arms 39A, 39B.

According to the present modification, it is possible to prevent the center robot CR (CR2) from becoming contaminated by the droplets dripping from the wet substrates. For example, it is possible to prevent failures of the center robot CR (CR2) due to such a contamination.

(4) In each of the embodiments and the modifications described above, each of the batch processing baths BT1 to BT6 handles the fifty substrates W arranged face-to-face at a half pitch. In this regard, each of the batch processing baths BT1 to BT6 may process the substrates W arranged in face-to-back so that the device surfaces of all the substrates W face the same direction. Each of the batch processing baths BT1 to BT6 may process the twenty-five substrates W corresponding one carrier C, and arranged at a full pitch. When the fifty substrates W are arranged face-to-back in the substrate holding unit 65, the Y-direction moving unit 102 moves the two chucks 71, 72 in the width direction Y in which the substrates W are aligned. That is, the Y-direction moving unit 102 moves the two chucks 71, 72 to and from the first substrate holding position and the second substrate holding position. As a result, the orientation converting unit 63 can extract twenty-five substrates W1 or twenty-five substrates W2.

(5) In each of the embodiments and the modifications described above, the single-wafer processing chamber SW2 performs the process of drying the substrate W using the supercritical fluid. In this regard, the single-wafer processing chamber SW2 may include a rotating processing unit 45 and a nozzle 47, similarly to the single-wafer processing chamber SW1. In such a configuration, the single-wafer processing chambers SW1, SW2 (or the single-wafer processing chambers SW1 to SW3) supplies pure water and IPA, for example, respectively, to the substrates W in the order listed herein, and then performs a drying process (spin drying) to the substrates W.

(6) In each of the embodiments and the modifications described above, for example, when the orientation converting unit 63 receives the substrates W from the substrate holding unit 65 in step S13, the lifting unit 67 as serving as a relative lifting unit raises and lowers the substrate holding unit 65. In this regard, the orientation converting unit 63 may include a lifting unit, and may receive the substrates W from the substrate holding unit 65 by lifting and lowering the two chucks 71, 72, the arm support 78, and the like. When the orientation converting unit 63 receives the substrates W from the substrate holding unit 65, the lifting unit of the orientation converting unit 63 and the lifting unit 67 may be raised and lowered together.

### REFERENCE SIGNS LIST

1 substrate processing apparatus
3 stocker block
5 transfer block
7 processing block
13A shelf
HTR substrate handling mechanism
15 first orientation converting mechanism
PP substrate delivery position
R1 batch processing area
R2 batch substrate transporting area
R3 orientation converting area
R4 single-wafer transporting area
R5 single-wafer processing area
27 buffering unit
BT1 to BT6 batch processing bath
WTR transporting mechanism
35 second orientation converting mechanism
CR, CR2 center robot
41 lifting stage
59 control unit
R31 substrate standby area
R32 orientation conversion executing area
LF9 lifter
63 orientation converting unit
65 substrate holding unit
71, 72 chuck
94 vertically rotating unit
95 horizontally moving unit
AX5 horizontal axis

1. A substrate processing apparatus configured to perform a batch process in which a plurality of substrates are processed as a batch, and a single-wafer process in which one substrate is processed at a time, continuously, the substrate processing apparatus comprising:
a carrier placing shelf on which a carrier is placed, with the carrier storing a plurality of substrates that are in a horizontal orientation at a predetermined interval along a vertical direction;
a transfer block that is positioned adjacently to the carrier placing shelf;
a processing block positioned adjacently to the transfer block; and
a substrate placing unit where a substrate is placed, wherein the transfer block includes:
a first orientation converting mechanism that converts the plurality of substrates in the horizontal orientation, the plurality of substrates having been taken out from the carrier, to a vertical orientation; and
a substrate handling mechanism that transports the plurality of substrates in the horizontal orientation as a batch, to and from the carrier placed on the carrier placing shelf, the first orientation converting mechanism, and the substrate placing unit, wherein
the processing block includes:
a batch processing area extending in a direction separating from the transfer block;
a batch substrate transporting area provided along the batch processing area, and having one end extending to the transfer block and another end extending in a direction separating from the transfer block;
an orientation converting area provided between the transfer block and the batch processing area;
a single-wafer transporting area positioned adjacently to the transfer block and to the orientation converting area; and
a single-wafer processing area positioned adjacently to the single-wafer transporting area,
the batch processing area includes a plurality of batch processing baths that process the plurality of substrates in the vertical orientation as a batch, and that are arranged in a direction in which the batch processing area extends,
the orientation converting area is provided with a second orientation converting mechanism that converts the plurality of substrates having been subjected to the batch process, from the vertical orientation to the horizontal orientation,
the batch substrate transporting area is provided with a batch substrate transporting mechanism that transfers the plurality of substrates in the vertical orientation to and from a substrate delivery position that is defined in the transfer block, the plurality of batch processing baths, and the second orientation converting mechanism,
the single-wafer processing area has a plurality of single-wafer processing chambers each of which processes one substrate in the horizontal orientation at a time,
the single-wafer transporting area has a horizontal substrate transporting mechanism that is capable of transporting one substrate in the horizontal orientation at a time, from and to the second orientation converting mechanism, the plurality of single-wafer processing chambers, and the substrate placing unit, and
the horizontal substrate transporting mechanism includes a hand that is horizontally movable and that holds a substrate in the horizontal orientation, and a lifting stage that raises and lowers the hand and that is at a fixed position in a horizontal direction.

2. The substrate processing apparatus according to claim 1, wherein the second orientation converting mechanism includes a substrate standby area and an orientation conversion executing area that are arranged in the direction in which the batch processing area extends,
the substrate standby area has a substrate holding unit that holds the plurality of substrates transported by the batch substrate transporting mechanism, in the vertical orientation,
the orientation conversion executing area has an orientation converting unit including: two chucks that hold the plurality of substrates; a vertically rotating unit that rotates the two chucks about a horizontal axis; and a horizontally moving unit that moves the two chucks and the vertically rotating unit from a position above the substrate holding unit to a preset position in the orientation conversion executing area, and
the orientation converting unit receives the plurality of substrates from the substrate holding unit by using the two chucks in the substrate standby area, and converts an orientation of the plurality of substrates from the vertical orientation to the horizontal orientation by using the vertically rotating unit in the orientation conversion executing area.

3. The substrate processing apparatus according to claim 1, wherein
the horizontal substrate transporting mechanism is suspended at a position above the single-wafer transporting area.

4. The substrate processing apparatus according to claim 1, wherein
the single-wafer processing area is provided on an opposite side of the transfer block with respect to the single-wafer transporting area, and is provided adjacently to the orientation converting area.

5. The substrate processing apparatus according to claim 4, wherein
the processing block further includes a second single-wafer processing area provided on an opposite side of the orientation converting area with respect to the single-wafer transporting area.

6. A substrate processing apparatus configured to perform a batch process in which a plurality of substrates are processed as a batch, and a single-wafer process in which one substrate is processed at a time, continuously, the substrate processing apparatus comprising:
a carrier placing shelf on which a carrier is placed, with the carrier storing a plurality of substrates that are in a horizontal orientation at a predetermined interval along a vertical direction;
a transfer block that is positioned adjacently to the carrier placing shelf;
a processing block that is positioned adjacently to the transfer block, wherein
the transfer block includes:
a first orientation converting mechanism that converts the plurality of substrates in the horizontal orientation, the plurality of substrates having been taken out from the carrier, to a vertical orientation;
a horizontal substrate transporting mechanism that transports a substrate in the horizontal orientation,
the processing block includes:
a batch processing area extending in a direction separating from the transfer block;
a batch substrate transporting area provided along the batch processing area, and having one end extending to the transfer block and another end extending in a direction separating from the transfer block;
an orientation converting area provided between the transfer block and the batch processing area;
a single-wafer transporting area positioned adjacently to the transfer block and to the orientation converting area; and
a single-wafer processing area positioned adjacently to the single-wafer transporting area,
the batch processing area is provided with a plurality of batch processing baths that process the plurality of substrates in the vertical orientation as a batch, and that are arranged in a direction in which the batch processing area extends,
the orientation converting area is provided with a second orientation converting mechanism that converts the plurality of substrates having been subjected to the batch process, from the vertical orientation to the horizontal orientation,
the batch substrate transporting area is provided with a batch substrate transporting mechanism that transfers the plurality of substrates in the vertical orientation to and from a substrate delivery position that is defined in the transfer block, the plurality of batch processing baths, and the second orientation converting mechanism,
the single-wafer processing area has a plurality of single-wafer processing chambers each of which processes one substrate in the horizontal orientation at a time,
the horizontal substrate transporting mechanism is capable of transporting a substrate in the horizontal orientation from and to the carrier placed on the carrier placing shelf, the first orientation converting mechanism, the second orientation converting mechanism, and the plurality of single-wafer processing chambers, and
the horizontal substrate transporting mechanism includes a hand that is horizontally movable and that holds a substrate in the horizontal orientation, and a lifting stage that raises and lowers the hand and that is at a fixed position in a horizontal direction.
